(19) United States
(12) Patent Application Publication
(10) Pub. No.: US 2025/0174434 A1
(43) Pub. Date: May 29, 2025

(54) PLASMA PROCESSING APPARATUS AND POWER SUPPLY SYSTEM

(71) Applicant: Tokyo Electron Limited, Tokyo (JP)

(72) Inventors: Kota SHIHOMMATSU, Miyagi (JP); Lifu LI, Miyagi (JP); Hiroshi TSUJIMOTO, Miyagi (JP); Daichi MIZUKAMI, Miyagi (JP); Jun ABE, Miyagi (JP); Hideo KATO, Miyagi (JP)

(73) Assignee: Tokyo Electron Limited, Tokyo (JP)

(21) Appl. No.: 19/037,464

(22) Filed: Jan. 27, 2025

Related U.S. Application Data
(63) Continuation of application No. PCT/JP2023/026442, filed on Jul. 19, 2023.

(30) Foreign Application Priority Data
Jul. 28, 2022 (JP) 2022-120800

(51) Int. Cl. H01J 37/32

(52) U.S. Cl. CPC H01J 37/32146; H01J 37/32128; H01J 37/32091; H01J 2237/334

(57) ABSTRACT

A plasma processing apparatus includes: an RF power supply that supplies an RF signal having a first power level during a first state and a second state in a first repetition period, a second power level during a third state in the first repetition period, and a third power level during a fourth state in the first repetition period, the second power level being less than the first power level, the third power level being less than the second power level; and a voltage pulse generator that applies a voltage pulse signal having a first voltage level during the first state in the first repetition period, and a sequence of voltage pulses having a second voltage level during the second state in the first repetition period, an absolute value of the second voltage level being greater than an absolute value of the first voltage level.

### CROSS-REFERENCE TO RELATED APPLICATIONS

This application is a continuation application of International Patent Application No. PCT/JP2023/026442, filed on Jul. 19, 2023, which claims priority from Japanese Patent Application No. 2022-120800, filed on Jul. 28, 2022, with the Japan Patent Office, the disclosure of each are incorporated herein in its entirety by reference.

### TECHNICAL FIELD

The present disclosure relates to a plasma processing apparatus and a power supply system.

### BACKGROUND

Japanese National Publication of International Patent Application No. 2013-535074 discloses supplying a multi-level RF power waveform, which has a first power level in at least a first pulse period and a second power level in a second pulse period, to a plasma source. Of the supplied gas, a first species is ionized in the first pulse period, and a second species is ionized in the second pulse period. Further, the '074 application proposes supplying a bias to a substrate in the first pulse period. The '074 application discloses controlling a substrate processing by applying the multi-level RF power to affect the number of ionized species, ions, and electrons, the temperature of electrons, and the plasma density.

### SUMMARY

According to an aspect of the present disclosure, a plasma processing apparatus includes: a plasma processing chamber; a substrate support disposed in the plasma processing chamber, and including a lower electrode; an upper electrode disposed above the substrate support; an RF power supply supplying an RF signal to the upper electrode or the lower electrode, the RF signal having a first power level during a first state and a second state in a first repetition period, a second power level during a third state in the first repetition period, and a third power level during a fourth state in the first repetition period, the second power level being less than the first power level, the third power level being less than the second power level; and a voltage pulse generator supplying a voltage pulse signal to the lower electrode, the voltage pulse signal having a first voltage level during the first state in the first repetition period, and a sequence of voltage pulses having a second voltage level during the second state in the first repetition period, an absolute value of the second voltage level being greater than an absolute value of the first voltage level.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a plasma processing system according to an embodiment.

FIG. 2 is a schematic cross-sectional view illustrating an example of a plasma processing apparatus according to an embodiment.

FIG. 3 is a view illustrating an RF signal and a DC signal.

FIGS. 4A to 4C are views illustrating an example of an RF signal and a DC signal according to a first embodiment.

FIG. 5 is a flowchart illustrating an example of an etching process according to the first embodiment.

FIGS. 6A to 6C are views illustrating the etching process according to the first embodiment.

FIG. 7 is a view illustrating an example of an RF signal and a DC signal according to a second embodiment.

FIG. 8 is a flowchart illustrating an example of an etching process according to the second embodiment.

FIG. 9 is a view illustrating another example of the RF signal and the DC signal according to the second embodiment.

FIG. 10 is a view illustrating yet another example of the RF signal and the DC signal according to the second embodiment.

FIG. 11 is a view illustrating an example of an RF signal and a DC signal according to a modification.

FIG. 12 is a view illustrating an example of an RF signal and a DC signal according to Modification 1.

FIG. 13 is a view illustrating an example of an RF signal and a DC signal according to Modification 2.

FIG. 14 is a view illustrating an example of an RF signal and a DC signal according to Modification 2-1.

FIG. 15 is a view illustrating an example of an RF signal and a DC signal according to Modification 2-2.

FIG. 16 is a view illustrating an example of an RF signal and a DC signal according to Modification 3.

FIG. 17 is a view illustrating an example of an RF signal and a DC signal according to Modification 4.

FIG. 18 is a view illustrating an example of an RF signal and a DC signal according to Modification 6.

### DETAILED DESCRIPTION

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

Hereinafter, embodiments of the present disclosure are described with reference to the drawings. In each drawing, the same components are denoted by the same reference numerals, and overlapping descriptions thereof may be omitted.

### <Plasma Processing System>

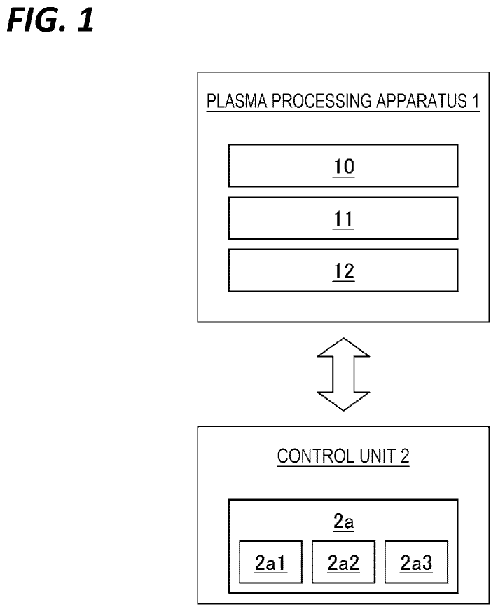

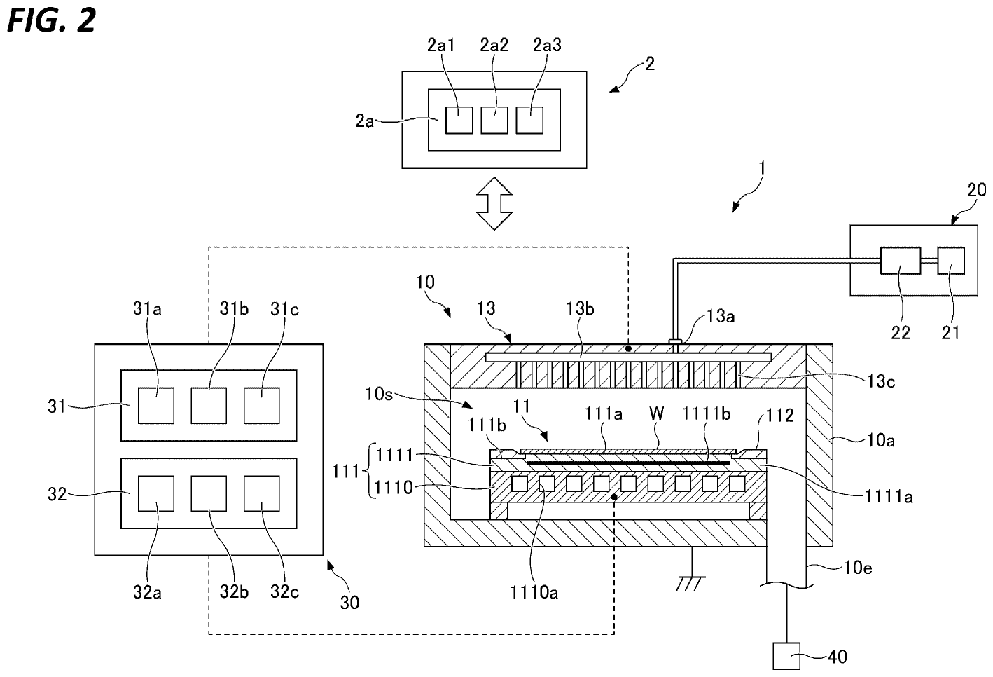

FIG. 1 is a view illustrating an example of a configuration of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 includes at least one gas supply port for supplying at least one processing gas to the plasma processing space and at least one gas discharge port for discharging the gas from the plasma processing space. The gas supply port is connected to a gas supply unit 20 (e.g., FIG. 2) to be described herein later, and the gas discharge port is connected to an exhaust system 40 (e.g., FIG. 2) to be described herein later. The substrate support 11 is disposed in the plasma processing space, and has a substrate support surface for supporting a substrate thereon.

The plasma generator 12 is configured to generate a plasma from at least one processing gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). In addition, various types of plasma generators may also be used, including an alternating current (AC) plasma generator and a direct current (DC) plasma generator. In an embodiment, an AC signal (AC power) used in the AC plasma generator has a frequency in the range of 100 kHz to 10 GHz. Thus, the AC signal includes a radio frequency (RF) signal and a microwave signal. In an embodiment, the RF signal has a frequency in the range of 100 kHz to 150 MHz.

The controller 2 processes computer-executable commands that cause the plasma processing apparatus 1 to perform various processes described herein below. The controller 2 may be configured to control each component of the plasma processing apparatus 1 to perform the various processes described herein below. In an embodiment, a portion of the controller 2 or the entire controller 2 may be included in the plasma processing apparatus 1. The controller 2 may include a processing unit 2al, a storage unit 2a2, and a communication interface 2a3. The controller 2 is implemented by, for example, a computer 2a. The processing unit 2al may be configured to perform various control operations by reading programs from the storage unit 2a2 and executing the read programs. The programs may be stored in the storage unit 2a2 in advance, or may be acquired via a medium when necessary. The acquired programs are stored in the storage unit 2a2, and read from the storage unit 2a2 to be executed by the processing unit 2al. The medium may be any of various storage media readable by the computer 2a, or may be a communication line connected to the communication interface 2a3. The processing unit 2al may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

Hereinafter, an example of a configuration of a capacitively coupled plasma processing apparatus, which is an example of the plasma processing apparatus 1, is described. FIG. 2 is a view illustrating an example of a configuration of the capacitively coupled plasma processing apparatus.

The capacitively coupled plasma processing apparatus 1 includes the plasma processing chamber 10, the gas supply unit 20, a power supply 30, and the exhaust system 40. Further, the plasma processing apparatus 1 includes the substrate support 11 and a gas introduction unit. The gas introduction unit is configured to introduce at least one processing gas into the plasma processing chamber 10. The gas introduction unit includes a showerhead 13. The substrate support 11 is disposed inside the plasma processing chamber 10. The showerhead 13 is disposed above the substrate support 11. In an embodiment, the showerhead 13 makes up at least a portion of the ceiling of the plasma processing chamber 10. The plasma processing chamber 10 has a plasma processing space 10s defined by the showerhead 13, the side wall 10a of the plasma processing chamber 10, and the substrate support 11. The plasma processing chamber 10 is grounded. The showerhead 13 and the substrate support 11 is electrically insulated from the housing of the plasma processing chamber 10.

The substrate support 11 includes a main body 111 and a ring assembly 112. The main body 111 has a central region 111a for supporting a substrate W, and an annular region 111b for supporting the ring assembly 112. A wafer is an example of the substrate W. The annular region 111b of the main body 111 surrounds the central region 111a of the main body 111 in plan view. The substrate W is placed on the central region 111a of the main body 111, and the ring assembly 112 is disposed on the annular region 111b of the main body 111 to surround the substrate W placed on the central region 111a of the main body 111. Accordingly, the central region 111a is referred to as the substrate support surface for supporting the substrate W, and the annular region 111b is referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 includes a ceramic member 1111a and an electrostatic electrode 1111b disposed inside the ceramic member 1111a. The ceramic member 1111a has the central region 111a. In an embodiment, the ceramic member 1111a also has the annular region 111b. Other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode connected to an RF power supply 31 and/or a DC power supply 32 to be described herein later may be disposed inside the ceramic member 1111a. In this case, the at least one RF/DC electrode serves as the lower electrode. In the case where a bias RF signal and/or a DC signal to be described herein later is supplied to the at least one RF/DC electrode, the RF/DC electrode is also referred to as a bias electrode. The conductive member of the base 1110 and the at least one RF/DC electrode may function as a plurality of lower electrodes. Further, the electrostatic electrode 1111b may function as the lower electrode. Thus, the substrate support 11 includes at least one lower electrode.

The ring assembly 112 includes one or more annular members. In an embodiment, the one or more annular members include one or more edge rings and at least one covering ring. The edge rings are formed of a conductive or insulating material, and the covering ring is formed of an insulating material.

The substrate support 11 may include a temperature adjustment module configured to adjust at least one of the electrostatic chuck 1111, the ring assembly 112, and the substrate to a target temperature. The temperature adjustment module may include a heater, a heat transfer medium, a flow path 1110a, or a combination thereof. A heat transfer fluid, such as brine or gas, flows in the flow path 1110a. In an embodiment, the flow path 1110a is formed inside the base 1110, and one or more heaters are disposed inside the ceramic member 1111a of the electrostatic chuck 1111. The substrate support 11 may further include a heat transfer gas supply unit configured to supply a heat transfer gas to the gap between the back surface of the substrate W and the central region 111a.

The showerhead 13 is configured to introduce at least one processing gas from the gas supply unit 20 into the plasma processing space 10s. The showerhead 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the showerhead 13 includes at least one upper electrode. The gas introduction unit may include one or more side gas injectors (SGIs) attached to one or more openings formed in the side wall 10a, in addition to the showerhead 13.

The gas supply unit 20 may include at least one gas source 21 and at least one flow controller 22. In an embodiment, the gas supply unit 20 is configured to supply at least one processing gas from each corresponding gas source 21 to the showerhead 13 via each corresponding flow controller 22. Each flow controller 22 may include, for example, a mass flow controller or a pressure control type flow controller. Further, the gas supply unit 20 may include at least one flow modulation device that modulates or pulses the flow rate of at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. Thus, plasma is formed from at least one processing gas supplied into the plasma processing space 10s. Accordingly, the RF power supply 31 may function as at least a portion of the plasma generator 12. Further, by supplying a bias RF signal to at least lower electrode, a bias potential is generated in the substrate W, so that ions components in the formed plasma may be drawn into the substrate W.

In an embodiment, the RF power supply 31 includes a first RF generator 31a, a second RF generator 31b, and an RF generator 31c. The first RF generator 31a is coupled to at least one lower electrode and/or at least one upper electrode via at least one impedance matching circuit, and configured to generate a source RF signal (source RF power) for plasma generation. In an embodiment, the source RF signal has a frequency in the range of 10 MHz to 150 MHz. In an embodiment, the first RF generator 31a may be configured to generate a plurality of source RF signals having different frequencies. The generated one or more source RF signals are supplied to at least one lower electrode and/or at least one upper electrode. The RF generator 31c is configured to generate an RF signal.

The second RF generator 31b is coupled to at least one lower electrode via at least one impedance matching circuit, and configured to generate a bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in the range of 100 kHz to 60 MHz. In an embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power supply 30 may further include a DC power supply 32 coupled to the plasma processing chamber 10. The DC power supply 32 includes a first DC generator 32a, a second DC generator 32b, and a DC generator 32c. In an embodiment, the first DC generator 32a is connected to at least one lower electrode, and configured to generate a first DC signal. The generated first DC signal is applied to at least one lower electrode. In an embodiment, the second DC generator 32b is connected to at least one upper electrode, and configured to generate a second DC signal. The generated second DC signal is applied to at least one upper electrode. The DC generator 32c is configured to generate a DC signal.

In various embodiments, the first and second DC signals may be pulsed. In this case, a sequence of voltage pulses is applied to at least one lower electrode and/or at least one upper electrode. Each voltage pulse may have a rectangular, trapezoidal, or triangular pulse waveform, or a combined pulse waveform thereof. In an embodiment, a waveform generator for generating the sequence of voltage pulses from the DC signal is connected between the first DC generator 32a and at least one lower electrode. Thus, the first DC generator 32a and the waveform generator make up a voltage pulse generator. When the second DC generator 32b and the waveform generator make up the voltage pulse generator, the voltage pulse generator is connected to at least one upper electrode. The voltage pulse may have a positive or negative polarity. Further, the sequence of voltage pulses may include one or more positive polarity voltage pulses and one or more negative polarity voltage pulses within one cycle. The first and second DC generators 32a and 32b may be provided in addition to the RF power supply 31, and the first DC generator 32a may be provided in place of the second RF generator 31b.

The exhaust system 40 may be connected to a gas discharge port 10e formed at, for example, the bottom of the plasma processing chamber 10. The exhaust system 40 may include a pressure regulating valve and a vacuum pump. The pressure in the plasma processing space 10s is regulated by the pressure regulating valve. The vacuum pump may include a turbo molecular pump, a dry pump, or a combination thereof.

Hereinafter, a pulsed RF signal supplied to the upper electrode or the lower electrode is referred to as an “RF signal.” The pulsed DC signal (voltage pulse signal) applied to the lower electrode is referred to as a “DC signal.” In the descriptions herein below, the pulsed RF signal is supplied to the lower electrode. However, without being limited thereto, the pulsed RF signal may be supplied to the upper electrode.

### <RF Signal/DC Signal>

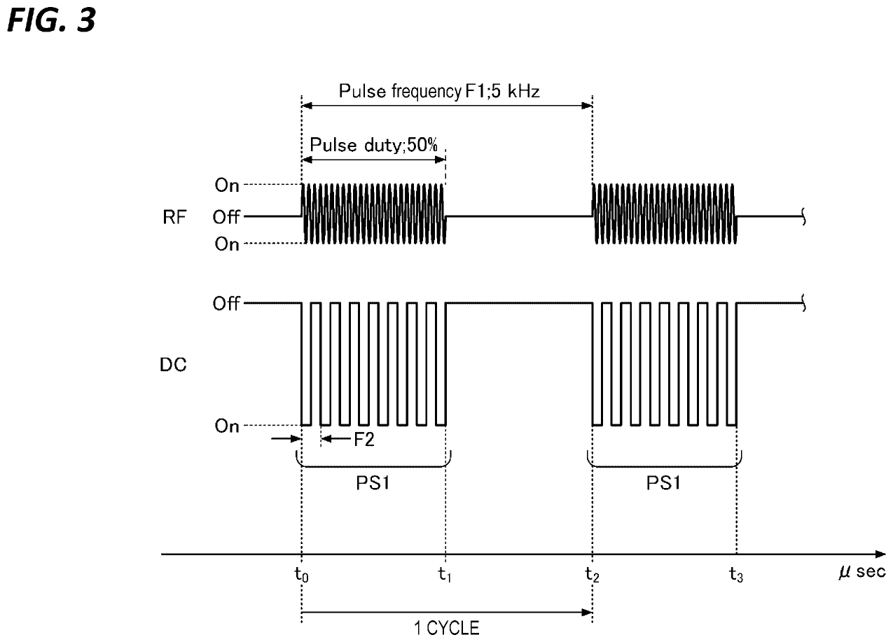

FIG. 3 is a view illustrating the RF signal and the DC signal. In the drawings herein below, the RF signal is described simply as “RF,” and the DC signal is described simply as “DC.” In the descriptions herein below, a pulsed source RF signal is described as an example of the RF signal. The source RF signal is an RF signal for plasma generation. In FIG. 3, the horizontal axis represents time, the vertical axis of RF represents a power level, and the vertical axis of DC represents a voltage level.

The RF signal and the DC signal are in the ON state during the period of times t₀ to t₁, and in the OFF state during the period of times t₁ to t₂. The ON state and the OFF state are repeated as one cycle. In the RF signal and the DC signal, a pulse frequency F1 falls within the range of 1 kHz to 50 kHz.

The RF signal has a frequency in the range of 100 kHz to 150 MHz during the ON state, and a zero power level during the OFF state. The DC signal has a sequence of voltage pulses PS1 during the ON state. The sequence of voltage pulses PS1 has a negative polarity voltage level, and the ON state (negative polarity voltage level) and the OFF state (zero voltage level) thereof are repeated in a second pulse period (pulse frequency F2). That is, the sequence of voltage pulses PS1 has the pulse frequency F2 greater than the pulse frequency F1. In an embodiment, the pulse frequency F2 falls within the range of 100 kHz to 1 MHz. In an embodiment, the pulse frequency F2 falls within the range of 300 kHz to 600 kHz.

A duty ratio (pulse duty) refers to time of the ON state of the RF signal relative to the total time of the ON state and the OFF state of the RF signal. In the example of FIG. 3, the duty ratio is 50%, and the ON and OFF states of the RF signal are periodically repeated such that the RF signal enters ON for ½ of one cycle and OFF for ½ of one cycle.

The duty ratio of the DC signal is the same as the duty ratio of the RF signal, and is 50%. The ON and OFF states of the DC signal are periodically repeated such that the DC signal enters ON for ½ of one cycle and OFF for ½ of one cycle. In the present disclosure, the DC signal maintains the zero voltage level during the OFF state, and the sequence of voltage pulses PS1 having the negative polarity voltage level during the ON state. In an embodiment, the sequence of voltage pulses PS1 repeats the zero voltage level and the negative polarity voltage level at the pulse frequency F2.

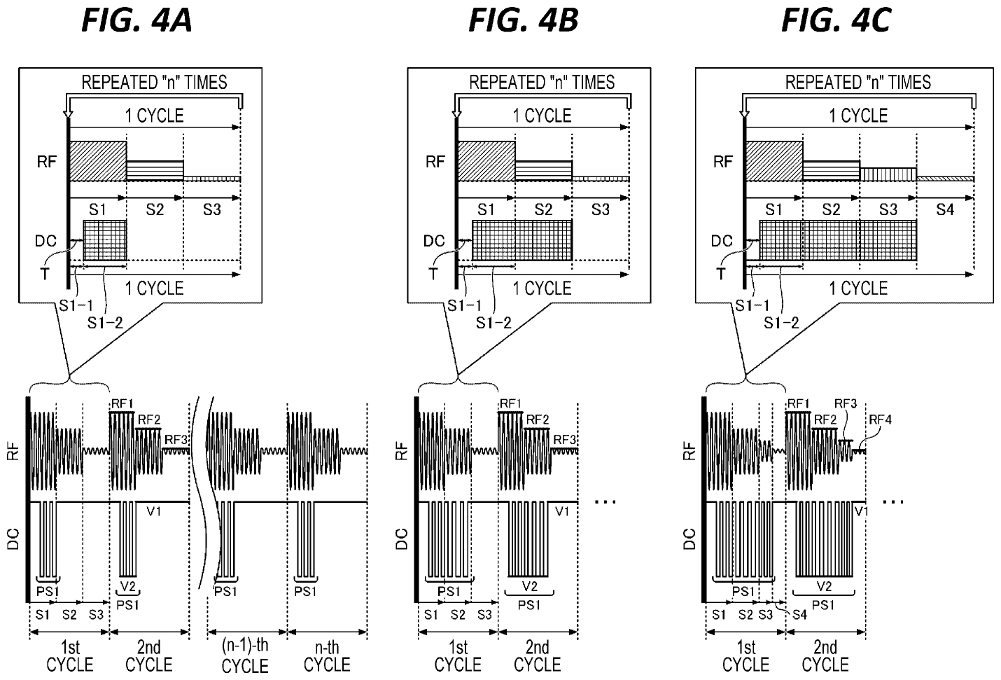

In FIGS. 4A to 4C and the subsequent drawings thereto, the RF signal and the DC signal have the pulse frequency F1 illustrated in FIG. 3, and the sequence of voltage pulses PS1 has the pulse frequency F2. While the RF signal of FIG. 3 has two power levels (ON state and OFF state) within one cycle, the RF signal in FIGS. 4A to 4C and the subsequent drawings has three or more power levels within one cycle.

### First Embodiment

Examples of the RF signal and the DC signal during an etching process according to a first embodiment are described with reference to FIGS. 4A to 4C. FIGS. 4A to 4C are views illustrating examples of the RF signal and the DC signal according to the first embodiment. The RF signal and the DC signal illustrated in FIGS. 4A to 4C are executed by the plasma processing apparatus 1, for example, in the manner that the controller 2 illustrated in FIGS. 1 and 2 controls the RF power supply 31 including the RF generator 31c and the DC power supply 32 including the DC generator 32c.

In the first embodiment, the RF signal has three power levels in one cycle of each of FIGS. 4A and 4B. Further, the RF signal has four power levels in one cycle of FIG. 4C.

In each of FIGS. 4A to 4C, the RF of the upper view represents the power level of the RF signal, and the RF of the lower view represents a pattern waveform of the RF signal having the power level represented in the upper view.

In each of FIGS. 4A to 4C, the DC of the upper view represents the voltage level of the DC signal, and the DC of the lower view represents a voltage pulse pattern of the DC signal having the voltage level represented in the upper view. In the present disclosure, the voltage pulse has a rectangular shape. However, without being limited thereto, the voltage pulse may have a rectangular, trapezoidal, or triangular shape, or a combined shape thereof.

The power level of the RF signal decreases in a stepwise pattern in one cycle. This cycle is repeated “n” times. The “n” indicates the predetermined set number of times, and is equal to or more than 1.

In FIGS. 4A and 4B, one cycle includes periods S1, S2, and S3. The one cycle is an example of a “first repetition period.” The first repetition period has a repetition frequency of 1 kHz to 50 kHz. The RF signal has a first power level RF1 during the period S1. The RF signal has a second power level RF2 during the period S2. The RF signal has a third power level RF3 during the period S3. The second power level RF2 is less than the first power level RF1, and the third power level RF3 is less than the second power level RF2.

In the first embodiment, the DC signal has two voltage levels in one cycle. The DC signal has a first voltage level V1 during a period T within the period S1 (hereinafter, referred to as “offset period T”), and the sequence of voltage pulses PS1 having a second voltage level V2 during the rest of the period S1. The DC signal has the first voltage level V1 during the periods S2 and S3. The offset period T within the period S1 may also be referred to as a “period S1-1.” The period other than the offset period T within the period of S1 may also be referred to as a “period 1-2.”

In FIGS. 4A and 4B, the RF signal has the first power level RF1 during a first state (period S1-1) within one cycle, and the first power level RF1 during a second state (period S1-2) within one cycle. Further, the RF signal has the second power level RF2 less than the first power level RF1 during a third state (period S2), and the third power level RF3 less than the second power level RF2 during a fourth state (period S3).

In FIG. 4A, the DC signal has the first voltage level V1 during the first state (period S1-1) within one cycle, and the sequence of voltage pulses PS1 having the second voltage level V2 during the second state (period S1-2) within one cycle. The absolute value of the second voltage level V2 is greater than the absolute value of the first voltage level V1. In an embodiment, the first voltage level V1 has a zero voltage level. The second voltage level V2 has a negative polarity. Further, the DC signal has the first voltage level V1 during the third state (period S2) within one cycle, and the first voltage level V1 during the fourth state (period S3) within one cycle.

In FIG. 4B, the DC signal has the first voltage level V1 during the first state (period S1-1) within one cycle, and the sequence of voltage pulses PS1 having the second voltage level V2 during the second state (period S1-2) and the third state (period S2) within one cycle. The absolute value of the second voltage level V2 is greater than the absolute value of the first voltage level V1. In an embodiment, the first voltage level V1 has a zero voltage level. The second voltage level V2 has a negative polarity. Further, the DC signal has the first voltage level V1 during the fourth state (period S3) within one cycle.

In FIG. 4C, one cycle includes periods S1, S2, S3, and S4. The one cycle is an example of the “first repetition period.” In FIG. 4C, the RF signal has the first power level RF1 during the first state (period S1-1) within one cycle, and the first power level RF1 during the second state (period S1-2) within one cycle. Further, the RF signal has the second power level RF2 less than the first power level RF1 during the third state (period S2), and the third power level RF3 less than the second power level RF2 during the fourth state (period S3). Further, the RF signal has a fourth power level RF4 less than the third power level RF3 during a fifth state (period S4).

In FIG. 4C, the DC signal has the first voltage level V1 during the first state (period S1-1) within one cycle, and the sequence of voltage pulses PS1 having the second voltage level V2 during the second state (period S1-2), the third state (period S2), and the fourth state (period S3) within one cycle. The absolute value of the second voltage level V2 is greater than the absolute value of the first voltage level V1. In an embodiment, the first voltage level V1 has a zero voltage level. The second voltage level V2 has a negative polarity. Further, the DC signal has the first voltage level V1 during the fifth state (period S4) within one cycle.

### <Etching Process>

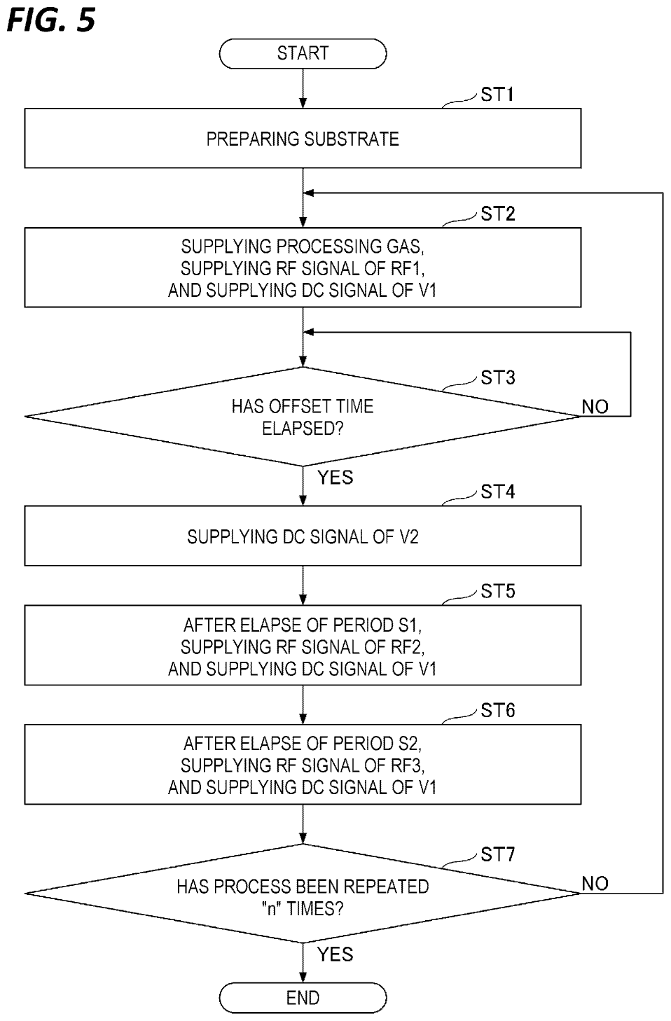

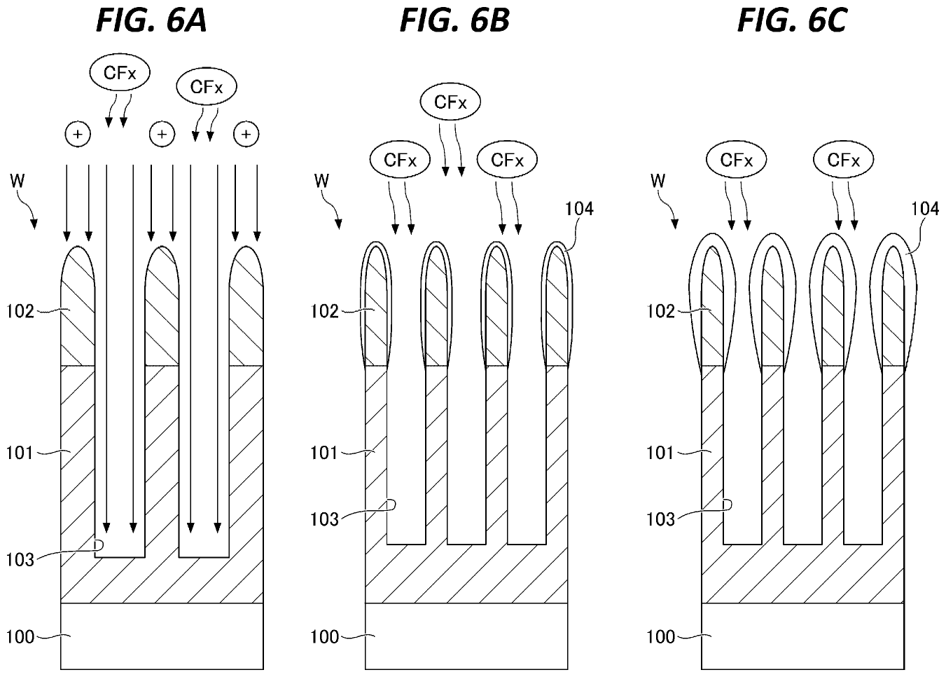

Next, with reference to FIGS. 5 and 6A to 6C, an etching process according to the first embodiment is described. FIG. 5 is a flowchart illustrating an example of the etching process according to the first embodiment. FIGS. 6A to 6C are views illustrating the etching process according to the first embodiment. The etching process of the present disclosure is controlled by the controller 2, and performed by the plasma processing apparatus 1.

When the etching process illustrated in FIG. 5 is started, in step ST1, the controller 2 places and prepares the substrate W on the substrate support 11. Next, in step ST2, the controller 2 supplies a processing gas for an etching, supplies the RF signal having the first power level RF1 during the period S1, and supplies the DC signal having the first voltage level V1 during the period S1-1.

Next, in step ST3, the controller 2 determines whether the offset period T has elapsed. The controller 2 waits until the offset period T elapses. After the offset period T elapses, in step ST4, the controller 2 supplies the DC signal having the sequence of voltage pulses PS1 having the second voltage level V2.

During the period S2 after the elapse of the period S1, in step ST5, the controller 2 supplies the RF signal having the second power level RF2 and the DC signal having the first voltage level V1.

During the period S3 after the elapse of the period S2, in step ST6, the controller 2 supplies the RF signal having the third power level RF3 and the DC signal having the first voltage level V1.

Next, in step ST7, the controller 2 determines whether the process above has been repeated the set “n” number of times. The controller 2 repeats steps ST2 to ST6 until reaching the set “n” number of times, and then, terminates the present process.

As illustrated in FIG. 4A, the plasma processing apparatus 1 according to the first embodiment may transition the DC signal from the sequence of voltage pulses PS1 having the second voltage level V2 to the first voltage level V1 (zero voltage level) upon the end of the period S1. As illustrated in FIG. 4B, the DC signal may be transitioned from the sequence of voltage pulses PS1 having the second voltage level V2 to the first voltage level V1 (zero voltage level) upon the end of the period S2. As illustrated in FIG. 4C, the DC signal may be transitioned from the sequence of voltage pulses PS1 having the second voltage level V2 to the first voltage level V1 (zero voltage level) upon the end of the period S3.

The timing for transitioning the DC signal to the sequence of voltage pulses PS1 having the second voltage level V2 is a timing after the offset period T elapses, but the offset period T may be “0.” In this case, the DC signal is transitioned to the second voltage level V2 at the beginning of the period S1. However, when the offset period T is larger than “0,” and the DC signal is transitioned to the second voltage level V2 after the elapse of the offset period, a favorable etching shape may be achieved.

At the time when the RF signal rises immediately after the beginning of the period S1, the RF signal does not reach the target power, and it takes time to reach the target power though it is momentary. Thus, at the rising time of the RF signal, plasma becomes unstable until the power reaches the first power level RF1 that is the target power, which affects the etching shape.

Accordingly, the controller 2 maintains the DC signal at the zero voltage level of the first voltage level V1 during the offset period T in which the RF signal rises. Then, after the elapse of the offset period T when plasma becomes stable, the DC signal is transitioned to the sequence of voltage pulses PS1 having the second voltage level V2.

As a result, ions in the plasma are drawn into a recess 103 of an etching target film 101 on a silicon substrate 100, as illustrated in FIG. 6A. Then, the ions etch the inside of the recess 103 vertically, so that the etching shape of the recess 103 may be favorably controlled.

The DC signal is supplied together with the RF signal, because when the RF signal is supplied without supplying the DC signal, reaction products generated by the etching are deposited, resulting in clogging the opening of the recess 103 formed in the substrate, which may cause the stop of etching. For example, when a CF-containing gas is supplied as the processing gas, the deposits may easily adhere to the mask 102 or the upper sidewall of the recess 103 of the etching target film 101. Thus, the opening of the recess 103 of the etching target film 101 formed in the substrate may be clogged by CFₓ-containing deposits.

Therefore, the DC signal having the sequence of voltage pulses PS1 of the second voltage level V2 is supplied to the lower electrode in the period S1-2. As a result, while depositing the CFₓ-containing deposits on the mask 102 and the upper sidewall of the recess 103 of the etching target film 101, the etching of the recess 103 is progressed by the ions. At this time, the mask 102 also is etched by the ions, but may be suppressed from being scraped by the ions since the CFₓ-containing deposits are deposited on the surface of the mask 102.

In the present disclosure, the DC signal is pulsed in the ON state. When the DC signal is not pulsed in the ON state, and the DC signal having the second voltage level V2 is continuously applied in, for example, the period S1-2, the electric potential of the substrate W does not change. Therefore, the ions may not be drawn into the substrate W.

Meanwhile, the DC signal of the present disclosure has the sequence of voltage pulses PS1 in, for example, the period S1-2. The sequence of voltage pulses PS1 repeats the second voltage level V2 and the first voltage level V1 at the pulse frequency F2. As a result, the ions may be drawn into the substrate W by the difference in electric potential of the substrate W between when the voltage of the first voltage level V1 is applied to the substrate W and when the voltage of the second voltage level V2 is applied to the substrate W.

In an embodiment, the sequence of voltage pulses PS1 has, for example, the pulse frequency F2 of 400 kHz. Thus, the sequence of voltage pulses PS1 repeats the first voltage level V1 (zero voltage level) and the second voltage level V2 (negative polarity) to accelerate the ions. As a result, the ions may be drawn even to the bottom of the recess of the etching target film, so that the controllability of the etching shape may be improved. That is, the etching shape of the recess 103 may be improved to become vertical, and the etching may be accelerated.

The RF signal decreases the power step by step during one cycle. Plasma tends to become unstable at the ignition time of plasma. Therefore, during the period S1, the power level is controlled to the highest level in one cycle in order to ensure the stable plasma ignition and generate plasma with a high plasma density.

During the period S2, the DC signal is maintained at a zero voltage level in FIG. 4A. Thus, the ions are not drawn into the substrate, and as illustrated in FIG. 6B, CFₓ-containing deposits 104 are deposited on the mask 102 and the upper portion of the recess 103 of the etching target film. At this time, the RF signal is controlled to a medium level. As a result, the electron density of the generated plasma decreases, as compared to that during the period S1, so that the deposition amount of CFₓ-containing deposits 104 generated during the etching may be reduced, and the opening of the recess 103 of the etching target film 101 may be suppressed from being clogged by the CFₓ-containing deposits 104.

During the period S3, the DC signal is maintained at a zero voltage level, and the RF signal is maintained at a power level even less than the power level during the period S2. Thus, the deposition amount of CFₓ-containing deposits 104 may be further reduced. Therefore, as illustrated in FIG. 6C, the CFₓ-containing deposits 104 may be deposited on the mask 102 without causing the clogging of the opening of the recess 103 in the etching target film 101. As a result, it is possible to reduce the damage to the mask 102 caused by the drawing of ions into the substrate as illustrated in FIG. 6A, in the next cycle.

In FIGS. 4B and 4C, the action of the sequence of voltage pulses PS1 increases relatively, each time the power level of the RF signal is decreased, as compared to FIG. 4A. As a result, the linearity of the ions may be improved, which may accelerate the etching, and the recess 103 of the etching target film 101 may be further etched deeper. However, since the action of the sequence of voltage pulses PS1 increases in the order of the sequence of FIG. 4C, the sequence of FIG. 4B, and the sequence of FIG. 4A, the mask 102 may be more easily scraped.

In the etching process according to the first embodiment, the patterns illustrated in FIGS. 4A to 4C are repeated for a plurality of cycles. As a result, a gradation may be imparted to the balance (degree) of intensity between the deposition of deposits on the mask 102 and the control of the etching shape of the etching target film 101. That is, the balance between the deposition of deposits on the mask 102 and the acceleration of etching of the etching target film 101 may be controlled. As a result, the controllability of the etching shape of the recess 103 of the etching target film 101 may be improved.

Further, at least one of the pulse frequencies F1 and F2, the RF frequency of the RF signal, and the duty ratio may be controlled. As a result, the intensity between the deposition of deposits on the mask 102 and the acceleration of etching of the etching target film 101 may be controlled more precisely, and the controllability of the etching shape of the recess 103 of the etching target film 101 may be improved.

### Second Embodiment

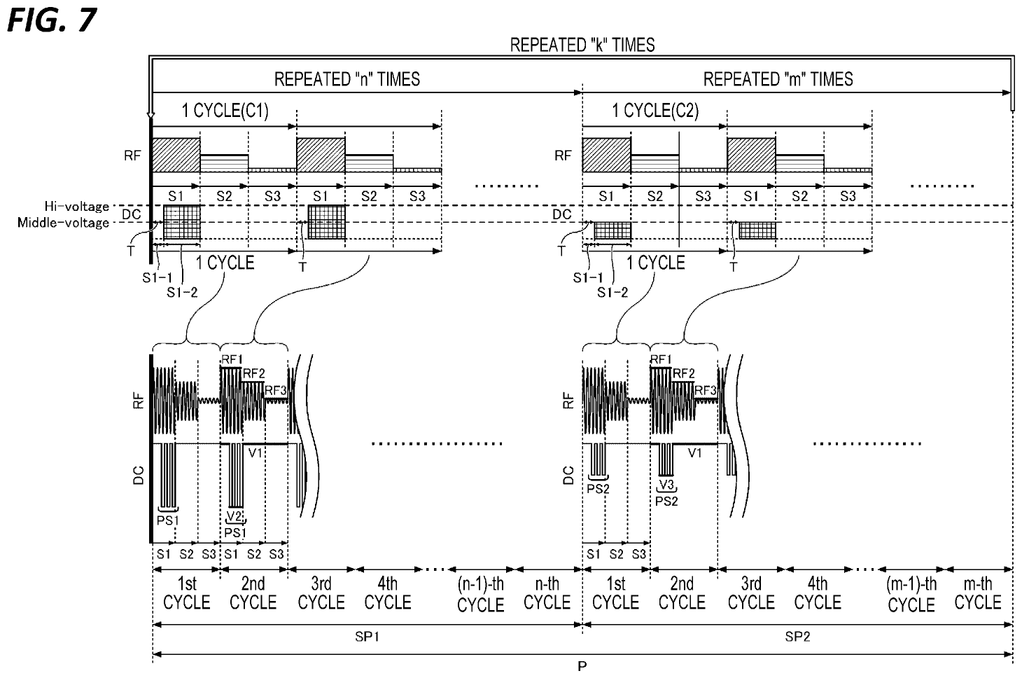

Next, examples of the RF signal and the DC signal during the etching process according to a second embodiment are described with reference to FIG. 7. FIG. 7 is a view illustrating examples of the RF signal and the DC signal according to the second embodiment.

The second embodiment is different from the first embodiment in that the DC signal has the sequence of voltage pulses PS1 having the second voltage level V2 and a sequence of voltage pulses PS2 having a third voltage level V3.

In the second embodiment as well, as illustrated in FIG. 7, the RF signal includes three power levels within one cycle, and the cycle is repeated multiple times.

In the example of FIG. 7, a main cycle P is repeated a “k” number of times. The main cycle P includes a first subcycle SP1 and a second subcycle SP2. The first subcycle SP1 includes a plurality of first cycles C1. In the example of FIG. 7, the first cycle C1 is repeated an “n” number of times in the first subcycle SP1. The second subcycle SP2 includes a plurality of second cycles C2. In the example of FIG. 7, the second cycle C2 is repeated an “m” number of times in the second subcycle SP2. Here, each of “n,” “m,” and “k” is the predetermined number of times, and equal to or more than 1. Each of the first cycle C1 and the second cycle C2 includes a first state S1, a second state S2, and a third state S3. The RF signal has a plurality of power levels that decreases in a stepwise pattern in the first cycle C1 and the second cycle C2.

In the example of FIG. 7, the RF signal has the first power level RF1 during the first state S1, the second power level RF2 less than the first power level RF1 during the second state S2, and the third power level RF3 less than the second power level RF2 during the third state S3. That is, in the example of FIG. 7, the RF signal has the same pulse pattern between the first cycle C1 and the second cycle C2. Further, in the example of FIG. 7, the DC signal has the first sequence of voltage pulses PS1 having the second voltage level V2 during the state S1-2 after the elapse of delay time S1-1 (offset period T) in the first state S1 within the first cycle C1. The DC signal has a second sequence of voltage pulses PS2 having the third voltage level V3 during the state S1-2 after the elapse of delay time S1-1 (offset period T) in the first state S1 within the second cycle C2. Further, in the example of FIG. 7, the DC signal has the first voltage level V1 during the delay time S1-1, the second state S2, and the third state S3 in both the first cycle C1 and the second cycle C2. The absolute value of the third voltage level V3 is less than the absolute value of the second voltage level V2. The absolute value of the first voltage level V1 is less than the absolute value of the third voltage level V3 and the absolute value of the second voltage level V2. The second voltage level V2 and the third voltage level V3 have a negative polarity. In an embodiment, the first voltage level V1 has a zero voltage level.

The first subcycle, in which the first repetition period is repeated multiple times (e.g., the “n” number of times), and the second subcycle, in which a second repetition period is repeated multiple times (e.g., the “m” number of times), are repeated alternately. The main cycle includes the first subcycle and the second subcycle, and a sequence of the first and second subcycles performed in the period P is repeated multiple times (e.g., the “k” number of times). In an embodiment, the main cycle has a repetition frequency of 1 Hz to 10 Hz.

In the example of FIG. 7, the first cycle C1 within the first subcycle SP1 includes the periods S1, S2, and S3, and is an example of the “first repetition period.” In the first subcycle SP1, the RF signal has the first power level RF1 during the first state (period S1-1) in the first cycle C1, and the first power level RF1 during the second state (period S1-2) in the first cycle C1. Further, the RF pulse signal has the second power level RF2 less than the first power level RF1 during the third state (period S2), and the third power level RF3 less than the second power level RF2 during the fourth state (period S3). In the first subcycle PS1, the first cycle C1 is repeated the “n” number of times.

In the first subcycle SP1, the DC signal has the first voltage level V1 during the first state (period S1-1) in the first cycle C1 within the first subcycle SP1, and the first sequence of voltage pulses PS1 having the second voltage level V2 during the second state (period S1-2) in the first cycle C1 within the first subcycle SP1. The absolute value of the second voltage level V2 is greater than the absolute value of the first voltage level V1. In an embodiment, the first voltage level V1 has a zero voltage level. The second voltage level V2 has a negative polarity. Further, the DC signal has the first voltage level V1 during the third state (period S2) in the first cycle C1, and the first voltage level V1 during the fourth state (period S3) in the first cycle C1.

In the example of FIG. 7, the second cycle C2 within the second subcycle SP2 includes the periods S1, S2, and S3, and is an example of the “second repetition period.” The second repetition period has a repetition frequency of 1 kHz to 50 kHz. The RF signal is the same between the first subcycle SP1 and the second subcycle SP2. The RF signal has the first power level RF1 during the first state (period S1-1) in the second cycle C2, and the first power level RF1 during the second state (period S1-2) in the second cycle C2. The RF signal has the second power level RF2 during the third state in the second cycle C2 (period S2), and the third power level RF3 during the fourth state in the second cycle C2 (period S3).

In the second subcycle SP2, the DC signal has the first voltage level V1 during the first state (period S1-1) in the second cycle C2 within the second subcycle SP2. Further, the DC signal has the second sequence of voltage pulses PS2 having the third voltage level V3 during the second state (period S1-2) in the second cycle C2. The absolute value of the third voltage level V3 is greater than the absolute value of the first voltage level V1, and less than the absolute value of the second voltage level V2. The third voltage level V3 has a negative polarity. Further, the DC signal has the first voltage level V1 during the third state (period S2) in the second cycle C2, and the first voltage level V1 during the fourth state (period S3) in the second cycle C2.

### <Etching Process>

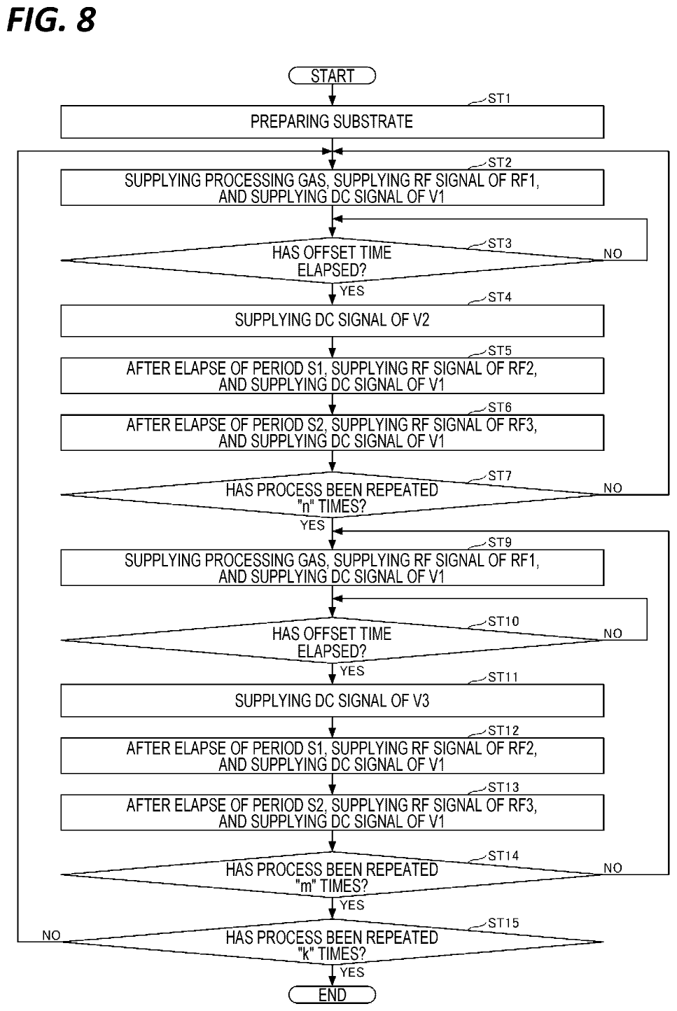

Next, the etching process according to the second embodiment is described with reference to FIG. 8. FIG. 8 is a flowchart illustrating an example of the etching process according to the second embodiment. The etching process of the present disclosure is controlled by the controller 2, and performed by the plasma processing apparatus 1. A step denoted by the same reference numeral as used in the etching process of the first embodiment illustrated in FIG. 5 indicates the same step performed in the etching process of the first embodiment, and is described in brief. Further, steps ST9, ST10, ST12, and ST13 are the same as steps ST2, ST3, ST5, and ST6.

When the etching process illustrated in FIG. 8 is started, the controller 2 performs steps ST1 to ST6. Thus, the first cycle of the first subcycle of the period SP1 in FIG. 7 is executed. In step ST7, the controller 2 determines whether the first subcycle has been repeated the “n” number of times.

When it is determined that the first subcycle has not been repeated the “n” number of times, the controller 2 returns to step ST2 to repeat steps ST2 to ST6. As a result, the process is performed from the second cycle to the n-th cycle of the first subcycle in sequence.

In step ST7, when it is determined that the first subcycle has been repeated the “n” number of times, the controller 2 performs steps ST9 to ST13. Thus, the first cycle of the second subcycle of the period SP2 in FIG. 7 is executed.

Steps ST9 to ST13 of the second subcycle are different from steps ST2 to ST6 of the first subcycle only in terms of step ST11. That is, in step ST4 of the first subcycle, the first sequence of voltage pulses PS1 having the second voltage level V2 is applied in the period S1-2, whereas in step ST9 of the second subcycle, the second sequence of voltage pulses PS2 having the third voltage level V3 is applied in the period S1-2. Thus, the drawing amount of ions may be changed in the first subcycle and the second subcycle.

In step ST14, the controller 2 determines whether the second subcycle has been repeated the “m” number of times. When it is determined that the second subcycle has not been repeated the “m” number of times, the controller 2 returns to step ST9 to repeat steps ST9 to ST13. Thus, the process is performed from the second cycle to the m-th cycle of the first subcycle in sequence.

In step ST14, when it is determined that the second subcycle has been repeated the “m” number of times, the controller 2 determines in step ST15 whether the main cycle has been repeated the “k” number of times. When it is determined that the main cycle has not been repeated the “k” number of times, the controller 2 returns to step ST2 to repeat steps ST2 to ST14. Thus, the process of the main cycle in the period P of FIG. 7 is repeated.

When it is determined in step ST15 that the main cycle has been repeated the “k” number of times, the controller 2 terminates the present process.

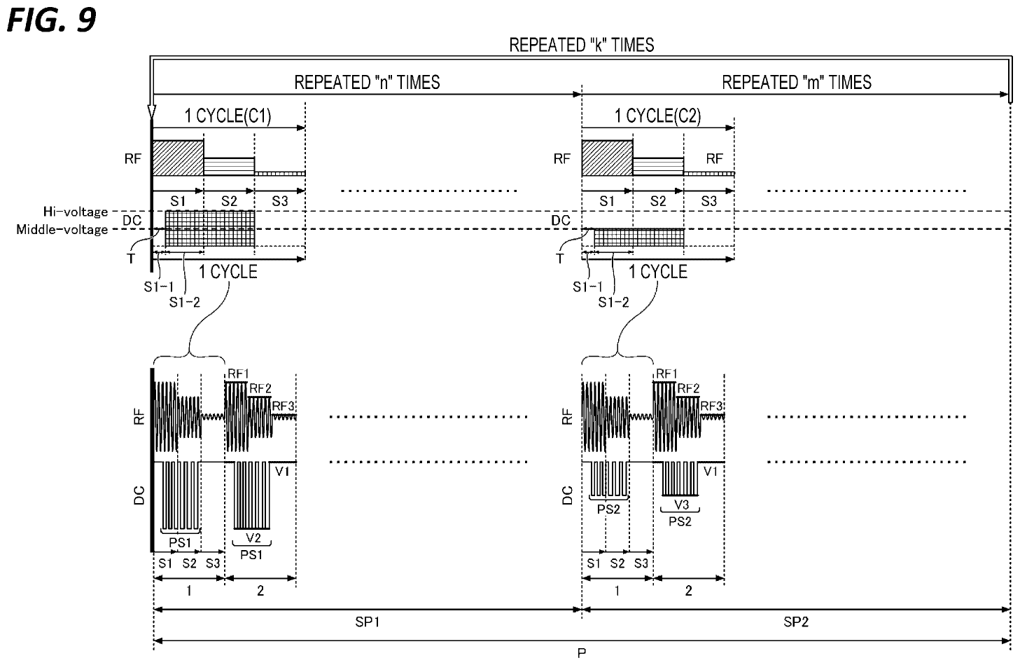

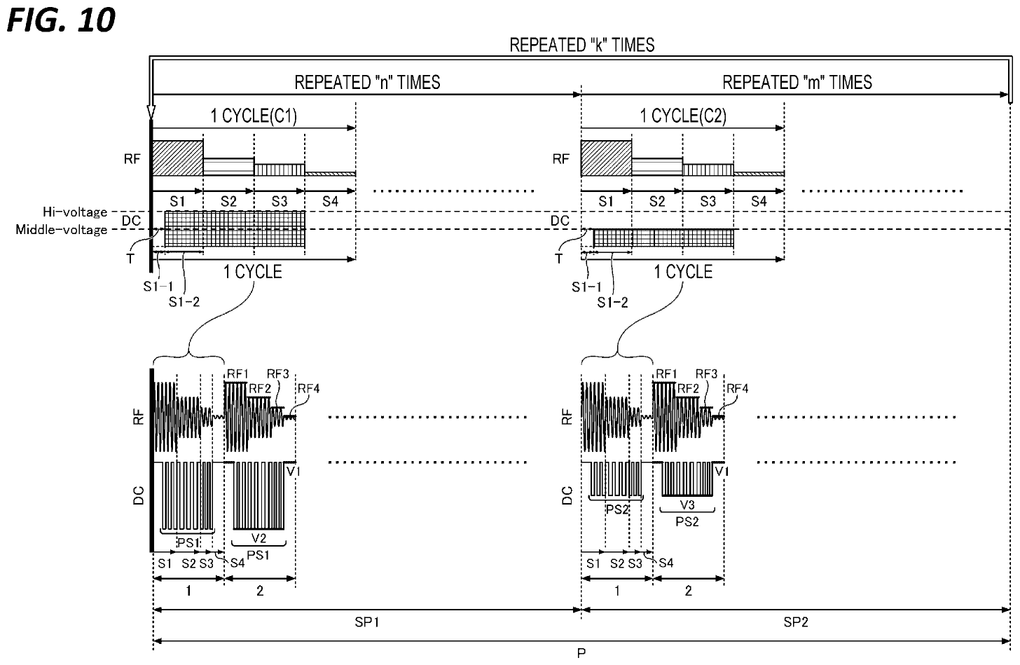

FIGS. 9 and 10 are views illustrating other examples of the RF signal and the DC signal according to the second embodiment. In FIG. 9, the RF signal has three power levels in one cycle, and this one cycle is repeated. In FIG. 10, the RF signal has four power levels in one cycle, and this one cycle is repeated.

The RF signal of FIG. 9 is the same as the RF signal of FIG. 7. The DC signal of FIG. 9 is different from the DC signal of FIG. 7. The DC signal of FIG. 7 transitions to the first voltage level V1 at the time of the transition from the period S1 to the period S2 in the first cycle C1, which is the first repetition period, and the second cycle C2, which is the second repetition period. Meanwhile, the DC signal of FIG. 9 transitions to the first voltage level V1 at the time of the transition from the period S2 to the period S3 in the first cycle C1 and the second cycle C2.

In the first subcycle SP1 of FIG. 10, the first cycle C1 includes the periods S1, S2, S3, and S4, and is an example of the “first repetition period.” In the first subcycle SP1, the RF signal has the first power level RF1 during the first state (period S1-1) in the first cycle C1, and the first power level RF 1 during the second state (period S1-2) in the first cycle C1. Further, the RF signal has the second power level RF2 less than the first power level RF1 during the third state (period S2) in the first cycle C1. The RF signal has the third power level RF3 less than the second power level RF2 during the fourth state (period S3) in the first cycle C1, and the fourth power level RF4 less than the third power level RF3 during the fifth state (period S4) in the first cycle C1.

In the first subcycle SP1 of FIG. 10, the DC signal has the first voltage level V1 during the first state (period S1-1) in the first cycle C1, and the sequence of voltage pulses PS1 having the second voltage level V2 during the second state (period S1-2), the third state (period S2), and the fourth state (period S3) in the first cycle C1. The absolute value of the second voltage level V2 is greater than the absolute value of the first voltage level V1. In an embodiment, the first voltage level V1 has a zero voltage level. The second voltage level V2 has a negative polarity. Further, the DC signal has the first voltage level V1 during the fifth state (period S4) in the first cycle C1.

In the second subcycle SP2 of FIG. 10, the second cycle C2 includes the periods S1, S2, S3, and S4, and is an example of the “second repetition period.” In the second subcycle SP2, the RF signal has the first power level RF1 during the first state (period S1-1) in the second cycle C2. The RF signal has the first power level RF1 during the second state (period S1-2) in the second cycle C2. The RF signal has the second power level RF2 during the third state (period S2) in the second cycle C2. The RF signal has the third power level RF3 during the fourth state (period S3) in the second cycle C2. The RF signal has the fourth power level RF4 during the fifth state (period S4) in the second cycle C2. The power levels RF1 to RF4 are the same between the first subcycle SP1 and the second subcycle SP2.

In the second subcycle SP2 of FIG. 10, the DC signal has the first voltage level V1 during the first state (period S1-1) in the second cycle C2 (one cycle), and the second sequence of voltage pulse PS2 having the third voltage level V3 during the second state (period S1-2), the third state (period S2), and the fourth state (period S3) in the second cycle C2. The absolute value of the third voltage level V3 is greater than the absolute value of the first voltage level V1, and less than the absolute value of the second voltage level V2. The third voltage level V3 has a negative polarity. The DC signal has the first voltage level V1 during the fifth state (period S4) in the second cycle C2.

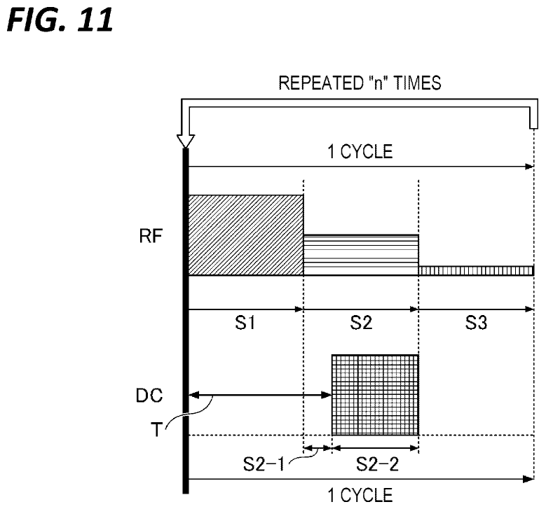

FIG. 11 is a view illustrating examples of the RF signal and the DC signal according to a modification. As illustrated in FIG. 11, the offset period T may be longer than the period S1. In the example of FIG. 11, the offset period T is longer than the period S1, and shorter than the total time of the periods S1 and S2. In FIG. 11, the DC signal has the first voltage level V1 during the first state (period S1) and the second state (period S2-1) within one cycle, and a sequence of voltage pulses having the second voltage level V2 during the third state (period S2-2) within one cycle. The absolute value of the second voltage level V2 is greater than the absolute value of the first voltage level V1. The second voltage level V2 has a negative polarity. The DC signal has the first voltage level V1 during the fourth state (period S3) within one cycle.

The RF signal has a plurality of power levels that decreases in a stepwise pattern in one cycle. The DC signal has the first voltage level V1 in the period S1, and has the first voltage level V1 until the offset period T elapses in the period S2. The DC signal has a sequence of voltage pulses having the second voltage level V2 after the offset period T elapses. The DC signal has the first voltage level V1 in the period S3.

### <Power Supply System>

The plasma processing apparatus 1 includes a power supply system used therein. The power supply system includes the RF generator 31c and the DC generator 32c.

The RF generator 31c for generating the RF signal is electrically connected between the first RF generator 31a and the upper electrode or the lower electrode.

The DC generator 32c for generating the DC signal is electrically connected between the first DC generator 32a and at least one lower electrode.

The power supply system used in the plasma processing apparatus includes the RF generator 31c and the DC generator 32c. The RF generator 31c is configured to generate the RF signal, and the RF signal has the first power level during the first state in the first repetition period, the first power level during the second state in the first repetition period, the second power level less than the first power level during the third state in the first repetition period, and the third power level less than the second power level during the fourth state in the first repetition period.

The DC generator 32c is configured to generate the DC signal, and the DC signal has the first voltage level during the first state in the first repetition period, and a sequence of voltage pulses having the second voltage level during the second state in the first repetition period. The absolute value of the second voltage level is greater than the absolute value of the first voltage level.

The DC generator 32c may generate the DC signal having the first voltage level during the third state in the first repetition period, and a sequence of voltage pulses having the first voltage level during the fourth state in the first repetition period.

The DC generator 32c may generate the DC signal having the second voltage level during the third state in the first repetition period, and a sequence of voltage pulses having the first voltage level during the fourth state in the first repetition period.

The RF generator 31c may generate the RF signal having the fourth power level less than the third power level during the fifth state in the first repetition period.

The DC generator 32c may generate the DC signal having the second voltage level during the third state in the first repetition period, the second voltage level during the fourth state in the first repetition period, and a sequence of voltage pulses having the first voltage level during the fifth state in the first repetition period.

The RF generator 31c and the DC generator 32c may generate the RF signal and the DC signals, respectively, as follows. The RF signal has the first power level RF1 during the first state in the second repetition period. The RF signal has the first power level RF1 during the second state in the second repetition period. The RF signal has the second power level RF2 during the third state in the second repetition period. The RF signal has the third power level RF3 during the fourth state in the second repetition period. The DC signal has the first voltage level during the first state in the second repetition period. The DC signal has a sequence of voltage pulses having the third voltage level during the second state in the second repetition period. The absolute value of the third voltage level is greater than the absolute value of the first voltage level, and less than the absolute value of the second voltage level.

The plasma processing apparatus 1 includes the plasma processing chamber 10, the substrate support 11 disposed in the plasma processing chamber 10, the RF generator 31c coupled to the plasma processing chamber 10 and configured to generate the RF signal having a plurality of power levels that decreases from the first power level in a stepwise pattern during a repetition period, and the DC generator 32c coupled to the substrate support 11 and configured to generate a sequence of voltage pulses during a pulse generation state in a repetition period. The beginning time point of the pulse generation state is offset with respect to the beginning time point of the first power level.

The pulse generation state may begin after the end of the first power level.

As described above, according to the plasma processing apparatus and the power supply system of the present embodiment, the controllability of the etching shape may be improved.

The timing for changing the DC signal to the first voltage level may deviate slightly from the end of the period S2 (or the end of the period S3 in the example of FIG. 11).

### Other Modifications

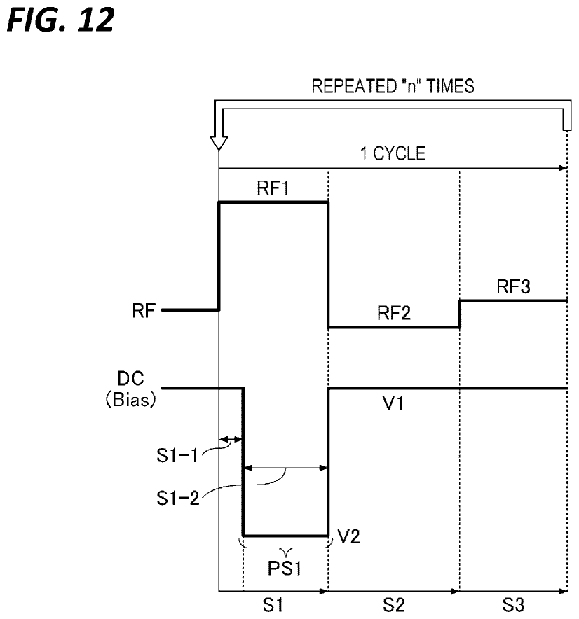

Modifications 1 to 7 are described with reference to FIGS. 12 to 18. The RF signal is generated by the RF generator 31c. The DC signal is generated by the DC generator 32c.

### Modification 1: 3 States

FIG. 12 is a view illustrating examples of an RF signal and a DC signal according to Modification 1. In the example of FIG. 12, the RF signal has the first power level RF1 during the first state (period S1-1) and the second state (period S1-2) in the first repetition period (one cycle). Further, the RF signal has the second power level RF2 less than the first power level during the third state (period S2) in the first repetition period. Further, the RF signal has the third power level RF3 less than the first power level RF1 and greater than the second power level RF2 during the fourth state (period S3) in the first repetition period.

The DC signal has the first voltage level V1 during the first state (period S1-1) in the first repetition period (one cycle), and the sequence of voltage pulses PS1 having the second voltage level V2 during the second state (period S1-2) in the first repetition period (one cycle). The absolute value of the second voltage level V2 is greater than the absolute value of the first voltage level V1.

### Modification 1-1

As illustrated in FIG. 12, the DC signal may have the first voltage level V1 during the third state (period S2) and the fourth state (period S3) in the first repetition period.

### Modification 1-2

The DC signal may have the sequence of voltage pulses PS1 having the second voltage level V2 during the third state (period S2) in the first repetition period, and the first voltage level V1 during the fourth state (period S3) in the first repetition period.

### Modification 1-3

The DC signal may have the sequence of voltage pulses PS1 having the second voltage level V2 during the third state (period S2) and the fourth state (period S3) in the first repetition period.

### Modification 2: 4 States

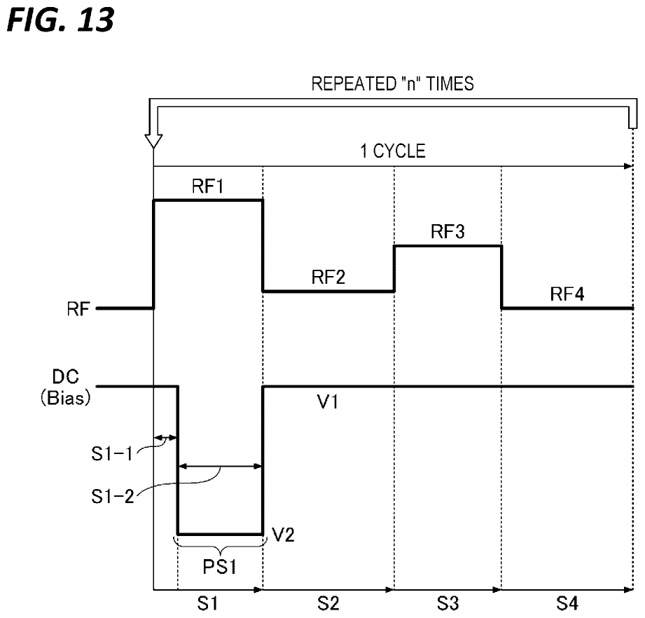

FIG. 13 is a view illustrating examples of an RF signal and a DC signal according to Modification 2. As illustrated in FIG. 13, the RF signal may have the fourth power level RF4 less than the second power level RF2 during the fifth state (period S4) in the first repetition period.

### Modification 2-1

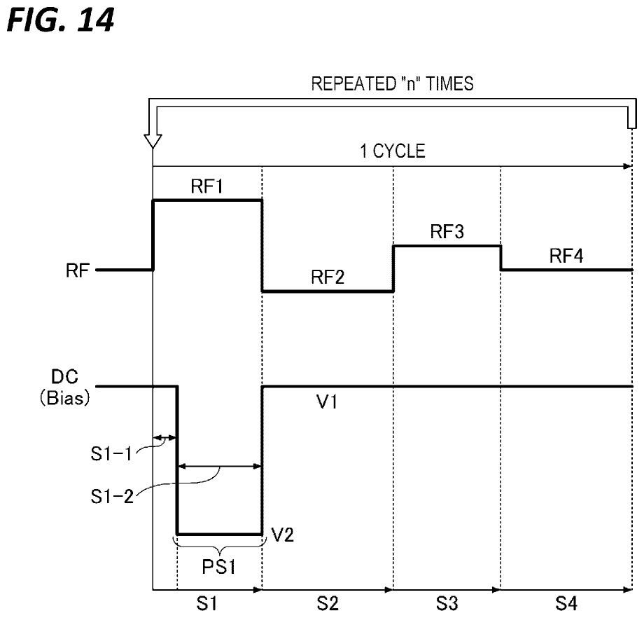

FIG. 14 is a view illustrating examples of an RF signal and a DC signal according to Modification 3. As illustrated in FIG. 14, the RF signal may have the fourth power level RF4 greater than the second power level RF2 and less than the third power level RF3 during the fifth state (period S4) in the first repetition period.

### Modification 2-2

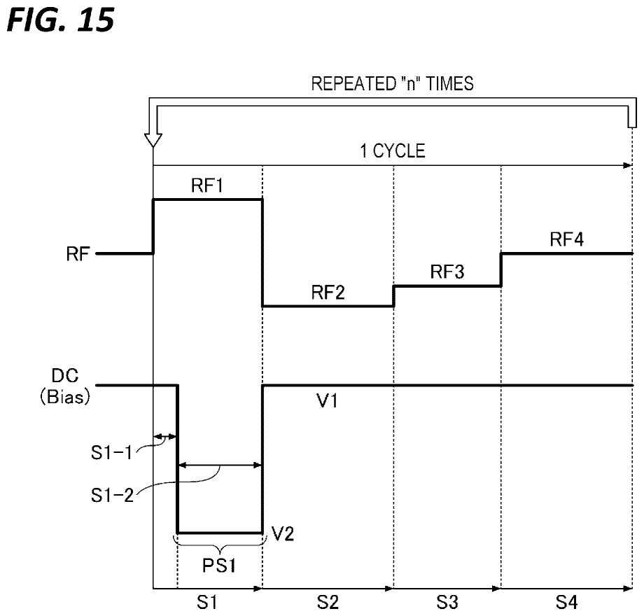

FIG. 15 is a view illustrating examples of an RF signal and a DC signal according to Modification 4. As illustrated in FIG. 15, the RF signal may have the fourth power level RF4 greater than the third power level RF3 and less than the first power level RF1 during the fifth state (period S4) in the first repetition period. The DC signal may have the first voltage level V1 during the third state (period S2), the fourth state (period S3), and the fifth state (period S4) in the first repetition period.

### Modification 2-3

The DC signal may have the sequence of voltage pulses PS1 having the second voltage level V2 during the third state (period S2) in the first repetition period, and the first voltage level V1 during the fourth state (period S3) and the fifth state (period S4) in the first repetition period.

### Modification 2-4

The DC signal may have the sequence of voltage pulses PS1 having the second voltage level V2 during the third state (period S2) and the fourth state (period S3) in the first repetition period, and the first voltage level V1 during the fifth state (period S4) in the first repetition period.

### Modification 2-5

The DC signal may have the sequence of voltage pulses PS1 having the second voltage level V2 during the third state (period S2), the fourth state (period S3), and the fifth state (period S4) in the first repetition period.

### Modification 2-6

The second voltage level V2 may have a negative polarity.

The first voltage level V1 may have a zero voltage level.

The first repetition period may have a repetition frequency of 1 kHz to 50 kHz.

The sequence of voltage pulses PS1 may have a pulse frequency of 300 kHz to 600 kHz.

### Modification 3: 4 States

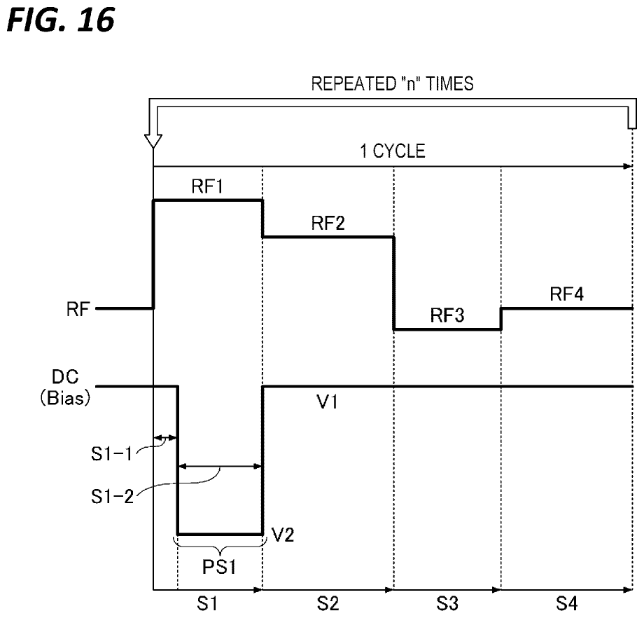

FIG. 16 is a view illustrating an example of an RF signal and a DC signal according to Modification 3. In the example of FIG. 16, the RF signal has the first power level RF1 during the first state (period S1-1) and the second state (period S1-2) in the first repetition period (one cycle). Further, the RF signal has the second power level RF2 less than the first power level RF1 during the third state (period S2) in the first repetition period. Further, the RF signal has the third power level RF3 less than the second power level RF2 during the fourth state (period S3) in the first repetition period. Further, the RF signal has the fourth power level RF4 greater than the third power level RF3 during the fifth state (period S4) in the first repetition period.

The DC signal has the first voltage level V1 during the first state (period S1-1) in the first repetition period (one cycle), and the sequence of voltage pulses PS1 having the second voltage level V2 during the second state (period S1-2) in the first repetition period (one cycle). The absolute value of the second voltage level V2 is greater than the absolute value of the first voltage level V1.

### Modification 3-1

As illustrated in FIG. 16, the fourth power level RF4 may be less than the second power level RF2.

The fourth power level RF4 may be less than the first power level RF1 and greater than the second power level RF2.

As illustrated in FIG. 16, the DC signal may have the first voltage level V1 during the third state (period S2), the fourth state (period S3), and the fifth state (period S4) in the first repetition period.

### Modification 3-2

The DC signal may have the sequence of voltage pulses PS1 having the second voltage level V2 during the third state (period S2) in the first repetition period, and the first voltage level V1 during the fourth state (period S3) and the fifth state (period S4) in the first repetition period.

### Modification 3-3

The DC signal may have the sequence of voltage pulses PS1 having the second voltage level V2 during the third state (period S2) and the fourth state (period S3) in the first repetition period, and the first voltage level V1 during the fifth state (period S4) in the first repetition period.

### Modification 3-4

The DC signal may have the sequence of voltage pulses PS1 having the second voltage level V2 during the third state (period S2), the fourth state (period S3), and the fifth state (period S4) in the first repetition period.

### Modification 3-5

The second voltage level V2 may have a negative polarity.

The first voltage level V1 may have a zero voltage level.

The first repetition period may have a repetition frequency of 1 kHz to 50 kHz.

In FIG. 16, the sequence of voltage pulses PS1 may have a pulse frequency of 300 kHz to 600 kHz.

### Modification 4: 3 States

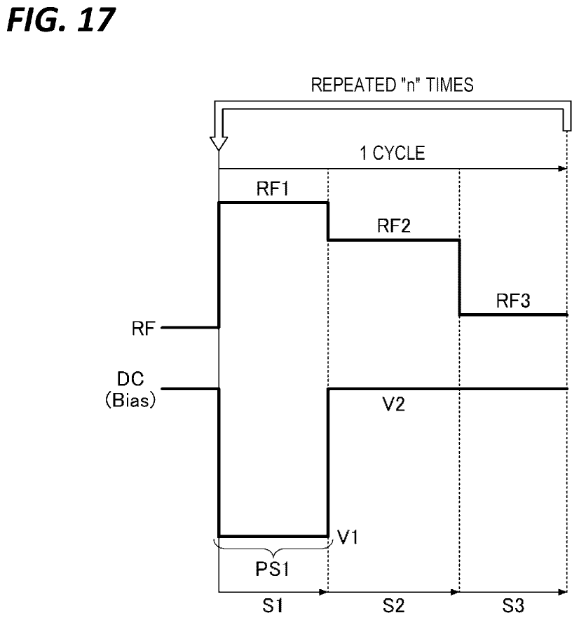

FIG. 17 is a view illustrating examples of an RF signal and a DC signal according to Modification 4. In the example of FIG. 17, the RF signal has the first power level RF1 during the first state (period S1) in the first repetition period (one cycle), the second power level RF2 less than the first power level RF1 during the second state (period S2) in the first repetition period, and the third power level RF3 less than the second power level RF2 during the third state (period S3) in the first repetition period.

The DC signal has the sequence of voltage pulses PS1 having the first voltage level V1 during the first state (period S1) in the first repetition period.

The DC signal has the second voltage level V2 during the second state (period S2) and the third state (period S3) in the first repetition period, and the absolute value of the second voltage level V2 is less than the absolute value of the first voltage level V1.

### Modification 4-1

The DC signal may have the sequence of voltage pulses PS1 having the first voltage level V1 during the second state (period S2) in the first repetition period, and the second voltage level V2 during the third state (period S3) in the first repetition period. The absolute value of the second voltage level V2 may be less than the absolute value of the first voltage level V1.

### Modification 4-2

The DC signal may have the sequence of voltage pulses PS1 having the first voltage level V1 between the second state (period S2) and the third state (period S3) in the first repetition period.

### Modification 5: 4 States

The RF signal may have the fourth power level RF4 less than the third power level RF3 during the fourth state (period S4) in the first repetition period.

### Modification 5-1

The RF signal may have the fourth power level RF4 higher than the third power level RF3 during the fourth state (period S4) in the first repetition period.

### Modification 5-2

The fourth power level RF4 may be less than the second power level RF2.

The fourth power level RF4 may be less than the first power level RF1 and higher than the second power level RF2.

### Modification 5-3

The DC signal may have the second voltage level V2 during the second state (period S2), the third state (period S3), and the fourth state (period S4) in the first repetition period, and the absolute value of the second voltage level V2 may be less than the absolute value of the first voltage level V1.

### Modification 5-4

The DC signal may have the sequence of voltage pulses PS1 having the first voltage level V1 during the second state (period S2) in the first repetition period, and the second voltage level V2 during the third state (period S3) and the fourth state (period S4) in the first repetition period. The absolute value of the second voltage level V2 may be less than the first voltage level V1.

### Modification 5-5

The DC signal may have the sequence of voltage pulses PS1 having the first voltage level V1 during the second state (period S2) and the third state (period S3) in the first repetition period, and the second voltage level V2 during the fourth state (period S4) in the first repetition period. The absolute value of the second voltage level V2 may be less than the absolute value of the first voltage level V1.

### Modification 5-6

The DC signal may have the sequence of voltage pulses PS1 having the first voltage level V1 during the second state (period S2), the third state (period S3), and the fourth state (period S4) in the first repetition period.

### Modification 6: 3 States

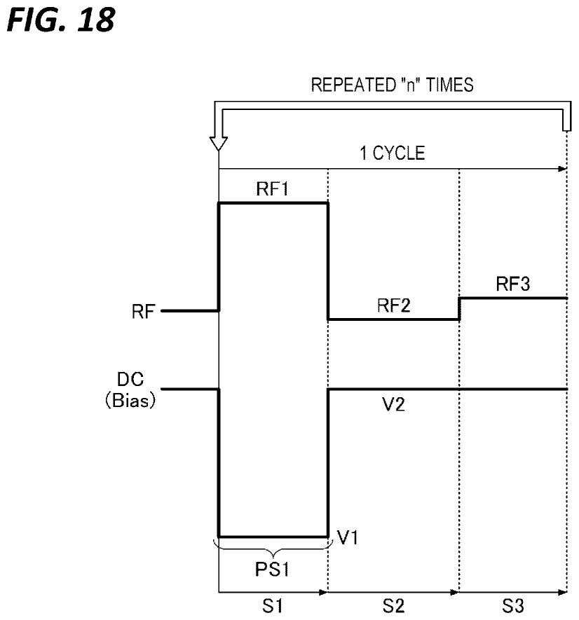

FIG. 18 is a view illustrating examples of an RF signal and a DC signal according to Modification 6. In the example of FIG. 18, the RF signal has the first power level RF1 during the first state (period S1) in the first repetition period (one cycle), the second power level RF2 less than the first power level RF1 during the second state (period S2) in the first repetition period, and the third power level RF3 less than the first power level RF1 and higher than the second power level RF2 during the third state (period S3) in the first repetition period.

The DC signal has the sequence of voltage pulses PS1 having the first voltage level V1 during the first state (period S1) in the first repetition period.

The DC signal has the second voltage level V2 during the second state (period S2) and the third state (period S3) in the first repetition period, and the absolute value of the second voltage level V2 is less than the absolute value of the first voltage level V1.

### Modification 6-1

The DC signal may have the sequence of voltage pulses PS1 having the first voltage level V1 during the second state (period S2) in the first repetition period, and the second voltage level V2 during the third state (period S3) in the first repetition period. The absolute value of the second voltage level V2 is less than the absolute value of the first voltage level V1.

### Modification 6-2

The DC signal may have the sequence of voltage pulses PS1 having the first voltage level V1 during the second state (period S2) and the third state (period S3) in the first repetition period.

### Modification 7: 4 States

The RF signal may have the fourth power level RF4 less than the second power level RF2 during the fourth state (period S4) in the first repetition period.

### Modification 7-1

The RF signal may have the fourth power level RF4 higher than the second power level RF2 and less than the third power level RF3 during the fourth state (period S4) in the first repetition period.

### Modification 7-2

The RF signal may have the fourth power level RF4 higher than the third power level RF3 and less than the first power level RF1 during the fourth state (period S4) in the first repetition period.

### Modification 7-3

The DC signal may have the second voltage level V2 during the second state (period S2), the third state (period S3), and the fourth state (period S4) in the first repetition period, and the absolute value of the second voltage level V2 may be less than the absolute value of the first voltage level V1.

### Modification 7-4

The DC signal may have the sequence of voltage pulses PS1 having the first voltage level V1 during the second state (period S2) in the first repetition period, and the second voltage level V2 during the third state (period S3) and the fourth state (period S4) in the first repetition period. The absolute value of the second voltage level V2 may be less than the absolute value of the first voltage level V1.

### Modification 7-5

The DC signal may have the sequence of voltage pulses PS1 having the first voltage level V1 during the second state (period S2) and the third state (period S3) in the first repetition period, and the second voltage level V2 during the fourth state (period S4) in the first repetition period. The absolute value of the second voltage level V2 may be less than the absolute value of the first voltage level V1.

### Modification 7-6

The DC signal may have the sequence of voltage pulses PS1 having the first voltage level V1 during the second state (period S2), the third state (period S3), and the fourth state (period S4) in the first repetition period.

The embodiments disclosed above include, for example, the following aspects.

### (Appendix 1)

A plasma processing apparatus including:
a plasma processing chamber;
a substrate support disposed in the plasma processing chamber, and including a lower electrode;
an upper electrode disposed above the substrate support;
an RF power supply supplying an RF signal to the upper electrode or the lower electrode, the RF signal having a first power level during a first state in a first repetition period, a first power level during a second state in the first repetition period, a second power level less than the first power level during a third state in the first repetition period, and a third power level less than the second power level during a fourth state in the first repetition period; and
a DC power supply supplying a DC signal to the lower electrode, the DC signal having a first voltage level during the first state in the first repetition period, and a sequence of voltage pulses having a second voltage level during the second state in the first repetition period, and an absolute value of the second voltage level being greater than an absolute value of the first voltage level.

### (Appendix 2)

The plasma processing apparatus described in Appendix 1, wherein the second voltage level has a negative polarity.

### (Appendix 3)

The plasma processing apparatus described in Appendix 2, wherein the first voltage level has a zero voltage level.

### (Appendix 4)

The plasma processing apparatus described in Appendix 2 or 3, wherein the first repetition period has a repetition frequency of 1 kHz to 50 kHz.

### (Appendix 5)

The plasma processing apparatus described in Appendix 4, wherein the sequence of voltage pulses has a pulse frequency of 300 kHz to 600 kHz.

### (Appendix 6)

The plasma processing apparatus described in any one of Appendixes 2 to 5, wherein the DC signal has the first voltage level during the third state in the first repetition period, and the first voltage level during the fourth state in the first repetition period.

### (Appendix 7)

The plasma processing apparatus described in any one of Appendixes 2 to 5, wherein the DC signal has the second voltage level during the third state in the first repetition period, and the first voltage level during the fourth state in the first repetition period.

### (Appendix 8)

The plasma processing apparatus described in Appendix 2, wherein the RF signal has a fourth power level less than the third power level during a fifth state in the first repetition period.

### (Appendix 9)

The plasma processing apparatus described in Appendix 8, wherein the DC signal has the second voltage level during the third state in the first repetition period, the second voltage level during the fourth state in the first repetition period, and the first voltage level during the fifth state in the first repetition period.

### (Appendix 10)

The plasma processing apparatus described in any one of Appendixes 2 to 5, wherein the RF signal has the first power level during the first state in a second repetition period, the first power level during the second state in the second repetition period, the second power level during the third state in the second repetition period, and the third power level during the fourth state in the second repetition period,
the DC signal has the first voltage level during the first state in the second repetition period, and a sequence of voltage pulses having the third voltage level during the second state in the second repetition period, and
an absolute value of the third voltage level is greater than an absolute value of the first voltage level, and less than an absolute value of the second voltage level.

### (Appendix 11)

The plasma processing apparatus described in Appendix 10, wherein a first subcycle, in which the first repetition period is repeated a plurality of times, and a second subcycle, in which the second repetition period is repeated a plurality of times, are repeated alternately.

### (Appendix 12)

The plasma processing apparatus described in Appendix 11, wherein a main cycle including the first subcycle and the second subcycle has a repetition frequency of 1 Hz to 10 Hz.

### (Appendix 13)

A power supply system for a plasma processing apparatus, the power supply system including:
an RF generator configured to generate an RF signal, the RF signal having a first power level during a first state in a first repetition period, a first power level during a second state in the first repetition period, a second power level less than the first power level during a third state in the first repetition period, and a third power level less than the second power level during a fourth state in the first repetition period; and
a DC generator configured to apply a DC signal, the DC signal having a first voltage level during the first state in the first repetition period, and a sequence of voltage pulses having a second voltage level during the second state in the first repetition period, and an absolute value of the second voltage level being greater than an absolute value of the first voltage level.

### (Appendix 14)

The power supply system described in Appendix 13, wherein the DC signal has the first voltage level during the third state in the first repetition period, and a sequence of voltage pulses having the first voltage level during the fourth state in the first repetition period.

### (Appendix 15)

The power supply system described in Appendix 13, wherein the DC signal has the second voltage level during the third state in the first repetition period, and a sequence of voltage pulses having the first voltage level during the fourth state in the first repetition period.

### (Appendix 16)

The power supply system described in Appendix 13, wherein the RF signal has a fourth power level less than the third power level during a fifth state in the first repetition period.

### (Appendix 17)

The power supply system described in Appendix 16, wherein the DC signal has the second voltage level during the third state in the first repetition period, the second voltage level during the fourth state in the first repetition period, and a sequence of voltage pulses having the first voltage level during the fifth state in the first repetition period.

### (Appendix 18)

The power supply system described in Appendix 13, wherein the RF signal has the first power level during the first state in a second repetition period, the first power level during the second state in the second repetition period, the second power level during the third state in the second repetition period, and the third power level during the fourth state in the second repetition period, and
the DC signal the first voltage level during the first state in the second repetition period, and a sequence of voltage pulses having the third voltage level during the second state in the second repetition period, and
an absolute value of the third voltage level is greater than an absolute value of the first voltage level, and less than an absolute value of the second voltage level.

### (Appendix 19)

A plasma processing apparatus including:
a plasma processing chamber;
a substrate support disposed in the plasma processing chamber;
an RF generator coupled to the plasma processing chamber, to generate an RF signal having a plurality of power levels that decreases in a stepwise pattern from a first power level during a repetition period; and
a DC generator coupled to the substrate support, to generate a sequence of voltage pulses during a pulse generation state in the repetition period, wherein a beginning time point of the pulse generation state is offset with respect to a beginning time point of the first power level.

### (Appendix 20)

The plasma processing apparatus described in Appendix 19, wherein the pulse generation state begins after an end of the first power level.

### (Appendix 21)

A power supply system for a plasma processing apparatus, the power supply system including:
an RF generator generating an RF signal, the RF signal having a first power level during a first state and a second state in a first repetition period, a second power level less than the first power level during a third state in the first repetition period, and a third power level less than the first power level and higher than the second power level during a fourth state in the first repetition period; and
a DC generator generating a DC signal, the DC signal having a first voltage level during the first state in the first repetition period, and a sequence of voltage pulses having a second voltage level during the second state in the first repetition period, and an absolute value of the second voltage level being greater than an absolute value of the first voltage level.

### (Appendix 22)

The power supply system described in Appendix 21, wherein the DC signal has the first voltage level during the third state and the fourth state in the first repetition period.

### (Appendix 23)

The power supply system described in Appendix 21, wherein the DC signal has a sequence of voltage pulses having the second voltage level during the third state in the first repetition period, and the first voltage level during the fourth state in the first repetition period.

### (Appendix 24)

The power supply system described in Appendix 21, wherein the DC signal has a sequence of voltage pulses having the second voltage level during the third state and the fourth state in the first repetition period.

### (Appendix 25)

The power supply system described in Appendix 21, wherein the RF signal has a fourth power level less than the second power level during a fifth state in the first repetition period.

### (Appendix 26)

The power supply system described in Appendix 21, wherein the RF signal has a fourth power level higher than the second power level and less than the third power level during the fifth state in the first repetition period.

### (Appendix 27)

The power supply system described in Appendix 21, wherein the RF signal has a fourth power level higher than the third power level and less than the first power level during a fifth state in the first repetition period.

### (Appendix 28)

The power supply system described in any one of Appendixes 25 to 27, wherein the DC signal has the first voltage level during the third state, the fourth state, and the fifth state in the first repetition period.

### (Appendix 29)

The power supply system described in any one of Appendixes 25 to 27, wherein the DC signal has a sequence of voltage pulses having the second voltage level during the third state in the first repetition period, and the first voltage level during the fourth state and the fifth state in the first repetition period.

### (Appendix 30)

The power supply system described in any one of Appendixes 25 to 27, wherein the DC signal has a sequence of voltage pulses having the second voltage level during the third state and the fourth state in the first repetition period, and the first voltage level during the fifth state in the first repetition period.

### (Appendix 31)

The power supply system described in any one of Appendixes 25 to 27, wherein the DC signal has a sequence of voltage pulses having the second voltage level during the third state, the fourth state, and the fifth state in the first repetition period.

### (Appendix 32)

The power supply system described in any one of Appendixes 21 to 31, wherein the second voltage level has a negative polarity.

### (Appendix 33)

The power supply system described in any one of Appendixes 21 to 32, wherein the first voltage level has a zero voltage level.

### (Appendix 34)

The power supply system described in any one of Appendixes 21 to 33, wherein the first repetition period has a repetition frequency of 1 kHz to 50 kHz.

### (Appendix 35)

The power supply system described in any one of Appendixes 21 to 34, wherein the sequence of voltage pulses has a pulse frequency of 300 kHz to 600 kHz.

### (Appendix 36)

A power supply system for a plasma processing apparatus, the power supply system including:
an RF generator generating an RF signal, the RF signal having a first power level during a first state and a second state in a first repetition period, a second power level less than the first power level during a third state in the first repetition period, a third power level less than the second power level during a fourth state in the first repetition period, and a fourth power level higher than the third power level during a fifth state in the first repetition period; and
a DC generator generating a DC signal, the DC signal having a first voltage level during the first state in the first repetition period, and a sequence of voltage pulses having a second voltage level during the second state in the first repetition period, and an absolute value of the second voltage level being greater than an absolute value of the first voltage level.

### (Appendix 37)

The power supply system described in Appendix 36, wherein the fourth power level is less than the second power level.

### (Appendix 38)

The power supply system described in Appendix 36, wherein the fourth power level is less than the first power level and higher than the second power level.

### (Appendix 39)

The power supply system described in any one of Appendixes 36 to 38, wherein the DC signal has the first voltage level during the third state, the fourth state, and the fifth state in the first repetition period.

### (Appendix 40)

The power supply system described in any one of Appendixes 36 to 38, wherein the DC signal has a sequence of voltage pulses having the second voltage level during the third state in the first repetition period, and the first voltage level during the fourth state and the fifth state in the first repetition period.

### (Appendix 41)

The power supply system described in any one of Appendixes 36 to 38, wherein the DC signal has a sequence of voltage pulses having the second voltage level during the third state and the fourth state in the first repetition period, and the first voltage level during the fifth state in the first repetition period.

### (Appendix 42)

The power supply system described in any one of Appendixes 36 to 38, wherein the DC signal has a sequence of voltage pulses having the second voltage level during the third state, the fourth state, and the fifth state in the first repetition period.

### (Appendix 43)

The power supply system described in any one of Appendixes 36 to 42, wherein the second voltage level has a negative polarity.

### (Appendix 44)

The power supply system described in any one of Appendixes 36 to 43, wherein the first voltage level has a zero voltage level.

### (Appendix 45)

The power supply system described in any one of Appendixes 36 to 44, wherein the first repetition period has a repetition frequency of 1 kHz to 50 kHz.

### (Appendix 46)

The power supply system described in any one of Appendixes 36 to 45, wherein the sequence of voltage pulses has a pulse frequency of 300 kHz to 600 kHz.

### (Appendix 47)

A power supply system for a plasma processing apparatus, the power supply system including:
an RF generator generating an RF signal, the RF signal having a first power level during a first state in a first repetition period, a second power level less than the first power level during a second state in the first repetition period, and a third power level less than the second power level during a third state in the first repetition period; and
a DC generator generating a DC signal, the DC signal having a sequence of voltage pulses having a first voltage level during the first state in the first repetition period.

### (Appendix 48)

The power supply system described in Appendix 47, wherein the DC signal has the second voltage level during the second state and the third state in the first repetition period, and an absolute value of the second voltage level is less than an absolute value of the first voltage level.

### (Appendix 49)

The power supply system described in Appendix 47, wherein the DC signal has a sequence of voltage pulses having a first voltage level during the second state in the first repetition period, and a second voltage level during the third state in the first repetition period, and an absolute value of the second voltage level is less than an absolute value of the first voltage level.

### (Appendix 50)

The power supply system described in Appendix 47, wherein the DC signal has a sequence of voltage pulses having the first voltage level during the second state and the third state in the first repetition period.

### (Appendix 51)

The power supply system described in Appendix 47, wherein the RF signal has a fourth power level less than the third power level during a fourth state in the first repetition period.

### (Appendix 52)

The power supply system described in Appendix 47, wherein the RF signal has a fourth power level higher than the third power level during a fourth state in the first repetition period.

### (Appendix 53)

The power supply system described in Appendix 52, wherein the fourth power level is less than the second power level.

### (Appendix 54)

The power supply system described in Appendix 52, wherein the fourth power level is less than the first power level and higher than the second power level.

### (Appendix 55)

The power supply system described in any one of Appendixes 51 to 54, wherein the DC signal has the second voltage level during the second state, the third state, and the fourth state in the first repetition period, and an absolute value of the second voltage level is less than an absolute value of the first voltage level.

### (Appendix 56)

The power supply system described in any one of Appendixes 51 to 54, wherein the DC signal has a sequence of voltage pulses having the first voltage level during the second state in the first repetition period, and the second voltage level during the third state and the fourth state in the first repetition period, and an absolute value of the second voltage level is less than an absolute value of the first voltage level.

### (Appendix 57)

The power supply system described in any one of Appendixes 51 to 54, wherein the DC signal has a sequence of voltage pulses having the first voltage level during the second state and the third state in the first repetition period, and the second voltage level during the fourth state in the first repetition period, and an absolute value of the second voltage level is less than an absolute value of the first voltage level.

### (Appendix 58)

The power supply system described in any one of Appendixes 51 to 54, wherein the DC signal has a sequence of voltage pulses having the first voltage level during the second state, the third state, and the fourth state in the first repetition period.

### (Appendix 59)

A power supply system for a plasma processing apparatus, the power supply system including:
an RF generator generating an RF signal, the RF signal having a first power level during a first state in a first repetition period, a second power level less than the first power level during a second state in the first repetition period, and a third power level less than the first power level and higher than the second power level during a third state in the first repetition period; and
a DC generator generating a DC signal, the DC signal having a sequence of voltage pulses having a first voltage level during the first state in the first repetition period,

### (Appendix 60)

The power supply system described in Appendix 59, wherein the DC signal has the second voltage level during the second state and the third state in the first repetition period, and an absolute value of the second voltage level is less than an absolute value of the first voltage level.

### (Appendix 61)

The power supply system described in Appendix 59, wherein the DC signal has a sequence of voltage pulses having a first voltage level during the second state in the first repetition period, and the second voltage level during the third state in the first repetition period, and an absolute value of the second voltage level is less than an absolute value of the first voltage level.

### (Appendix 62)

The power supply system described in Appendix 59, wherein the DC signal has a sequence of voltage pulses having the first voltage level during the second state and the third state in the first repetition period.

### (Appendix 63)

The power supply system described in Appendix 59, wherein the RF signal has a fourth power level less than the second power level during a fourth state in the first repetition period.

### (Appendix 64)

The power supply system described in Appendix 59, wherein the RF signal has a fourth power level higher than the second power level and less than the third power level during the fourth state in the first repetition period.

### (Appendix 65)

The power supply system described in Appendix 59, wherein the RF signal has a fourth power level higher than the third power level and less than the first power level during the fourth state in the first repetition period.

### (Appendix 66)

The power supply system described in any one of Appendixes 63 to 65, wherein the DC signal has a second voltage level during the second state, the third state, and the fourth state in the first repetition period, and an absolute value of the second voltage level is less than an absolute value of the first voltage level.

### (Appendix 67)

The power supply system described in any one of Appendixes 63 to 65, wherein the DC signal has a sequence of voltage pulses having the first voltage level during the second state in the first repetition period, and the second voltage level during the third state and the fourth state in the first repetition period, and an absolute value of the second voltage level is less than an absolute value of the first voltage level.

### (Appendix 68)

The power supply system described in any one of Appendixes 63 to 65, wherein the DC signal has a sequence of voltage pulses having the first voltage level during the second state and the third state in the first repetition period, and the second voltage level during the fourth state in the first repetition period, and an absolute value of the second voltage level is less than an absolute value of the first voltage level.

### (Appendix 69)

The power supply system described in any one of Appendixes 63 to 65, wherein the DC signal has a sequence of voltage pulses having the first voltage level during the second state, the third state, and the fourth state in the first repetition period.

The present disclosure is not limited to the configurations included in the embodiments described herein, and may include, for example, combinations of the configurations of the embodiments with other elements. The configurations of the embodiments may be modified within the scope that does not depart from the gist of the present disclosure, and the modifications may be made appropriately according to application forms. The matters described in the plurality of embodiments above may adopt other configurations or be combined with each other within the scope that does not cause any inconsistency. In the embodiments above, descriptions are made assuming, for example, a capacitively coupled plasma apparatus. However, the present disclosure is not limited thereto, and may be applied to other plasma apparatuses. For example, an inductively coupled plasma (ICP) apparatus may be used, instead of the capacitively coupled plasma apparatus. In this case, the inductively coupled plasma apparatus includes an antenna and a lower electrode. The lower electrode is disposed inside a substrate support, and the antenna is disposed above a chamber or on the top of the chamber. The RF generator is coupled to the antenna, and the DC generator is coupled to the lower electrode. Thus, the RF generator is coupled to the upper electrode of the capacitively coupled plasma apparatus or the antenna of the inductively coupled plasma apparatus. That is, the RF generator is coupled to the plasma processing chamber 10.

According to an aspect of the present disclosure, the controllability of an etching shape may be improved.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a plasma processing chamber;
a substrate support disposed in the plasma processing chamber, and including a lower electrode;
an upper electrode disposed above the substrate support;
a radio-frequency (RF) power supply configured to supply an RF signal to the upper electrode or the lower electrode, the RF signal having a first power level during a first state and a second state in a first repetition period, a second power level during a third state in the first repetition period, and a third power level during a fourth state in the first repetition period, the second power level being less than the first power level, the third power level being less than the second power level; and
a voltage pulse generator configured to apply a voltage pulse signal to the lower electrode, the voltage pulse signal having a first voltage level during the first state in the first repetition period, and a sequence of voltage pulses having a second voltage level during the second state in the first repetition period, an absolute value of the second voltage level being greater than an absolute value of the first voltage level.

2. The plasma processing apparatus according to claim 1, wherein the second voltage level has a negative polarity.

3. The plasma processing apparatus according to claim 2, wherein the first voltage level has a zero voltage level.

4. The plasma processing apparatus according to claim 2, wherein the first repetition period has a repetition frequency of 1 kHz to 50 kHz.

5. The plasma processing apparatus according to claim 4, wherein the sequence of voltage pulses has a pulse frequency of 300 kHz to 600 kHz.

6. The plasma processing apparatus according to claim 2, wherein the voltage pulse signal has the first voltage level during the third state in the first repetition period, and the first voltage level during the fourth state in the first repetition period.

7. The plasma processing apparatus according to claim 2, wherein the voltage pulse signal has the second voltage level during the third state in the first repetition period, and the first voltage level during the fourth state in the first repetition period.

8. The plasma processing apparatus according to claim 2, wherein the RF signal has a fourth power level less than the third power level during a fifth state in the first repetition period.

9. The plasma processing apparatus according to claim 8, wherein the voltage pulse signal has the second voltage level during the third state in the first repetition period, the second voltage level during the fourth state in the first repetition period, and the first voltage level during the fifth state in the first repetition period.

10. The plasma processing apparatus according to claim 1, wherein the RF signal has the first power level during the first state in a second repetition period, the first power level during the second state in the second repetition period, the second power level during the third state in the second repetition period, and the third power level during the fourth state in the second repetition period,
the voltage pulse signal has the first voltage level during the first state in the second repetition period, and a sequence of voltage pulses having the third voltage level during the second state in the second repetition period, and
an absolute value of the third voltage level is greater than an absolute value of the first voltage level, and less than an absolute value of the second voltage level.

11. The plasma processing apparatus according to claim 10, wherein a first subcycle, in which the first repetition period is repeated a plurality of times, and a second subcycle, in which the second repetition period is repeated a plurality of times, are repeated alternately.

12. The plasma processing apparatus according to claim 11, wherein a main cycle including the first subcycle and the second subcycle has a repetition frequency of 1 Hz to 10 Hz.

13. A power supply system for a plasma processing apparatus, the power supply system comprising:
an RF generator configured to generate an RF signal, the RF signal having a first power level during a first state and a second state in a first repetition period, a second power level during a third state in the first repetition period, and a third power level during a fourth state in the first repetition period, the second power level being less than the first power level, the third power level being less than the second power level; and
a voltage pulse generator configured to apply a voltage pulse signal, the voltage pulse signal having a first voltage level during the first state in the first repetition period, and a sequence of voltage pulses having a second voltage level during the second state in the first repetition period, an absolute value of the second voltage level being greater than an absolute value of the first voltage level.

14. The power supply system according to claim 13, wherein the voltage pulse signal has the first voltage level during the third state in the first repetition period, and a sequence of voltage pulses having the first voltage level during the fourth state in the first repetition period.

15. The power supply system according to claim 13, wherein the voltage pulse signal has the second voltage level during the third state in the first repetition period, and a sequence of voltage pulses having the first voltage level during the fourth state in the first repetition period.

16. The power supply system according to claim 13, wherein the RF signal has a fourth power level less than the third power level during a fifth state in the first repetition period.

17. The power supply system according to claim 16, wherein the voltage pulse signal has the second voltage level during the third state in the first repetition period, the second voltage level during the fourth state in the first repetition period, and a sequence of voltage pulses having the first voltage level during the fifth state in the first repetition period.

18. The power supply system according to claim 13, wherein the RF signal has the first power level during the first state in a second repetition period, the first power level during the second state in the second repetition period, the second power level during the third state in the second repetition period, and the third power level during the fourth state in the second repetition period, and
the voltage pulse signal has the first voltage level during the first state in the second repetition period, and a sequence of voltage pulses having the third voltage level during the second state in the second repetition period, and
an absolute value of the third voltage level is greater than an absolute value of the first voltage level, and less than an absolute value of the second voltage level.

19. A plasma processing apparatus comprising:
a plasma processing chamber;
a substrate support disposed in the plasma processing chamber;
an RF generator coupled to the plasma processing chamber, and configured to generate an RF signal having a plurality of power levels that decreases in a stepwise pattern from a first power level during a repetition period; and
a voltage pulse generator coupled to the substrate support, and configured to generate a sequence of voltage pulses during a pulse generation state in the repetition period, wherein a beginning time point of the pulse generation state is offset with respect to a beginning time point of the first power level.

20. The plasma processing apparatus according to claim 19, wherein the pulse generation state begins after an end of the first power level.
